(19) United States
(12) Patent Application Publication
(10) Pub. No.: US 2016/0247576 A1
(43) Pub. Date: Aug. 25, 2016

(54) MEMORY CONTROLLER AND OPERATING METHOD THEREOF

(71) Applicant: SK hynix Inc., Gyeonggi-do (KR)

(72) Inventor: Sang-Hyun PARK, Gyeonggi-do (KR)

(21) Appl. No.: 14/835,287

(22) Filed: Aug. 25, 2015

(30) Foreign Application Priority Data
Feb. 23, 2015 (KR) 10-2015-0025197

(51) Int. Cl. G11C 16/26; G11C 11/56

(52) U.S. Cl. CPC G11C 16/26; G11C 11/56

(57) ABSTRACT

An operating method of a memory controller includes: performing a first hard decision read operation based on a read retry table including an index representing a read environment of a semiconductor memory device, wherein the read retry table defines hard read voltage values for a plurality of hard read voltage levels of a multi-level cell; and performing a second hard decision read operation by independently changing each of the hard read voltage levels based on the hard read voltage values of the read retry table when the first hard decision read operation fails.

### CROSS-REFERENCE TO RELATED APPLICATIONS

The present application claims priority of Korean Patent Application No. 10-2015-0025197, filed on Feb. 23, 2015, which is incorporated herein by reference in its entirety.

### BACKGROUND

1. Field

Various exemplary embodiments of the present invention relate to a semiconductor design technology and, more particularly, to a memory controller and an operating method thereof.

2. Description of the Related Art

Semiconductor memory devices are generally classified into volatile memory devices, such as Dynamic Random Access Memory (DRAM) and Static RAM (SRAM), and nonvolatile memory devices, such as Read Only Memory (ROM), Mask ROM (MROM), Programmable ROM (PROM), Erasable PROM (EPROM), Electrically EPROM (EEPROM), Ferromagnetic RAM (FRAM), Phase change RAM (PRAM), Magnetoresistive RAM (MRAM), Resistive RAM (RRAM) and flash memory.

Volatile memory devices lose their stored data when their power supply is interrupted, whereas nonvolatile memory devices retain their data even without a constant source of power. Flash memory devices are widely used as a storage medium in computer systems because of their high program speed, low power consumption and large data storage capacity.

In nonvolatile memory devices, especially in flash memory devices, data states storable in each memory cell are determined based on the number of bits stored in the memory cell. A memory cell storing 1-bit data per cell is called a single-bit cell or a single-level cell (SLC). A memory cell storing multiple bits of data (i.e., 2 or more bits data) per cell is called a multi-bit cell, a multi-level cell (MLC) or a multi-state cell. The multi-bit cell is advantageous because it allows more data to be stored in a limited area. However, as the number of bits programmed in each memory cell increases, the reliability decreases and the read failure rate increases.

For example, when k bits are to be programmed in a memory cell, one of 2^{k} threshold voltages is formed in the memory cell. Due to minute differences between the electrical characteristics of memory cells, the threshold voltages of memory cells programmed with the same data form a threshold voltage distribution. Threshold voltage distributions correspond to 2^{k} data values having k-bit information, respectively.

However, the voltage window available for threshold voltage distributions is limited. Therefore, as the value k increases, the distance between the threshold voltage distributions decreases and the adjacent threshold voltage distributions overlap each other. As the adjacent threshold voltage distributions overlap each other, read data may include error bits.

FIG. 1 is a threshold voltage distribution of program and erase states of a 3-bit multi-level cell (3-bit MLC) in a nonvolatile memory device.

FIG. 2 is a threshold voltage distribution illustrating program and erase states after characteristic deterioration in a 3-bit MLC nonvolatile memory device.

In an MLC nonvolatile memory device, e.g., an MLC flash memory device in which k-bit data is programmed in a memory cell, the memory cell may have one of 2^{k} threshold voltage distributions. For example, a 3-bit MLC has one of 8 threshold voltage distributions.

Threshold voltages of memory cells programmed with the same data form the threshold voltage distribution due to characteristic differences between memory cells. In a 3-bit MLC nonvolatile memory device, as illustrated in FIG. 1, threshold voltage distributions having first to seventh program states ‘P1’ to ‘P7’ and an erase state ‘E’ are formed. FIG. 1 shows an ideal case in which threshold voltage distributions do not overlap and have read voltage margins therebetween.

Referring to the flash memory example of FIG. 2, the memory cell may experience charge loss where the electrons trapped at a floating gate or tunnel oxide film are discharged over time. Such charge loss may accelerate when the tunnel oxide film deteriorates by iterative program and erase operations. Charge loss results in a decrease in the threshold voltages of memory cells. For example, as illustrated in FIG. 2, the threshold voltage distribution may shift left due to charge loss.

Further, program disturbance, erase disturbance and/or back pattern dependency also cause increases in threshold voltages. As characteristics of memory cells deteriorate, as described above, threshold voltage distributions of adjacent states may overlap, as illustrated in FIG. 2.

Once threshold voltage distributions overlap, read data may include a significant number of errors when a particular read voltage is applied to a selected word line. For example, when a sensed state of a memory cell according to a read voltage Vread3 that is applied to a selected word line is on, the memory cell is determined to have a second program state ‘P2’. When a sensed state of a memory cell according to a read voltage Vread3 applied to a selected word line is off, the memory cell is determined to have a third program state ‘P3’. However, when threshold voltage distributions overlap, the memory cell, which actually has the third program state ‘P3’, may be incorrectly determined to have the second program state ‘P2’. In short, when the threshold voltage distributions overlap as illustrated in FIG. 2, read data may include a significant number of errors.

What is therefore required is a scheme for precisely determining optimal read voltages for data stored in memory cells of a semiconductor memory device.

### SUMMARY

Various embodiments of the present invention are directed to a memory controller and an operating method thereof capable of precisely determining optimal read voltages for data stored in memory cells.

In accordance with an embodiment of the present invention, an operating method of a memory controller may include: performing a first hard decision read operation based on a read retry table including an index representing a read environment of a semiconductor memory device, wherein the read retry table defines hard read voltage values for a plurality of hard read voltage levels to a multi-level cell; and performing a second hard decision read operation by independently changing each of the plurality of hard read voltage levels based on the hard read voltage values of the read retry table when the first hard decision read operation fails.

Preferably, the second hard decision read operation may be performed in response to the plurality of hard read voltage levels by sequentially changing the hard read voltage values for each of the plurality of hard read voltage levels in response to the index of the read retry table.

Preferably, the second hard decision read operation may be performed in response to the plurality of hard read voltage levels by sequentially changing the plurality of hard read voltage levels.

Preferably, the second hard decision read operation may change a first hard read voltage level while fixing the other hard read voltage levels among the plurality of hard read voltage levels.

Preferably, the second hard decision read operation may fix the other hard read voltage levels to the hard read voltage values defined by the read retry table.

Preferably, after the second hard decision read operation is performed in response to a first hard read voltage level by sequentially changing the hard read voltage values for the first hard read voltage level, the second hard decision read operation may be performed in response to a second hard read voltage level when the second hard decision read operation in response to the first hard read voltage level fails. Preferably, the first and second hard read voltage levels may be included in the plurality of hard read voltage levels.

Preferably, the first hard decision read operation may be performed when a hard decision read operation in response to the plurality of hard read voltage levels that are set to initial hard read voltage values fails.

Preferably, the operation method may further include performing a soft decision read operation when the second hard decision read operation in response to all of the hard read voltage values of the read retry table fails.

Preferably, one or more of the first and second hard decision read operations and the soft decision read operation may be performed based on a low density parity check (LDPC) decoding process.

Preferably, the read environment of the semiconductor memory device may include one or more of a retention characteristic and a read disturbance characteristic.

In accordance with an embodiment of the present invention, a memory controller may include: a first means for performing a first hard decision read operation based on a read retry table including an index representing a read environment of a semiconductor memory device, wherein the read retry table defines hard read voltage values for a plurality of hard read voltage levels to a multi-level cell; and a second means for performing a second hard decision read operation by independently changing each of the plurality of hard read voltage levels based on the hard read voltage values of the read retry table when the first hard decision read operation fails.

Preferably, the second means may perform the second hard decision read operation in response to the plurality of hard read voltage levels by sequentially changing the hard read voltage values for each of the plurality of hard read voltage levels in response to the index of the read retry table.

Preferably, the second means may perform the second hard decision read operation in response to the plurality of hard read voltage levels by sequentially changing the plurality of hard read voltage levels.

Preferably, the second means may change a first hard read voltage level while fixing the other hard read voltage levels among the plurality of hard read voltage levels.

Preferably, the second means may fix the other hard read voltage levels to the hard read voltage values defined by the read retry table.

Preferably, after the second means performs the second hard decision read operation in response to a first hard read voltage level by sequentially changing the hard read voltage values for the first hard read voltage level, the second means may perform the second hard decision read operation in response to a second hard read voltage level when the second hard decision read operation in response to the first hard read voltage level fails. Preferably, the first and second hard read voltage levels may be included in the plurality of hard read voltage levels.

Preferably, the first means may perform the first hard decision read operation when a hard decision read operation in response to the plurality of hard read voltage levels that are set to initial hard read voltage values falls.

Preferably, the memory controller may further include a third means for performing a soft decision read operation when the second hard decision read operation in response to all of the hard read voltage values of the read retry table fails.

Preferably, one or more of the first to third means may perform the first and second hard decision read operations and the soft decision read operation based on a low density parity check (LDPC) decoding process.

Preferably, the read environment of the semiconductor memory device may include one or more of a retention characteristic and a read disturbance characteristic.

In accordance with various embodiments of the present invention, an optimal read voltage for data stored in memory cell of a semiconductor memory device may be effectively determined.

### BRIEF DESCRIPTION OF THE DRAWINGS

FIG. 1 is a threshold voltage distribution schematically illustrating program and erase states of a 3-bit multi-level cell (3-bit MLC) nonvolatile memory device.

FIG. 2 is a threshold voltage distribution schematically illustrating program and erase states due to characteristic deterioration of a 3-bit MLC nonvolatile memory device.

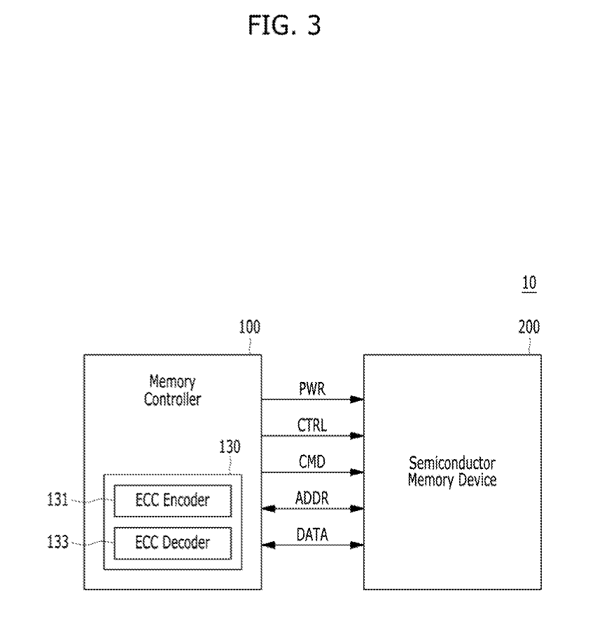

FIG. 3 is a block diagram schematically illustrating a semiconductor memory system in accordance with an embodiment of the present invention.

FIG. 4A is a detailed block diagram illustrating the semiconductor memory system shown in FIG. 3.

FIG. 4B is a circuit diagram illustrating a memory block shown in FIG. 4A.

FIG. 5 is a flowchart illustrating an operation of a memory controller shown in FIG. 4A.

FIG. 6 is a schematic diagram illustrating read retry tables included in a memory controller shown in FIG. 4A.

FIGS. 7A and 7B are schematic diagrams illustrating a read error.

FIG. 7C is a schematic diagram illustrating a read retry operation.

FIG. 8A is a schematic diagram illustrating an operation of determining a hard read voltage according to a comparison example.

FIG. 8B is a schematic diagram illustrating an operation of determining a hard read voltage in accordance with an exemplary embodiment of the present invention.

FIG. 8C is a flowchart illustrating an operation of a memory controller in accordance with an exemplary embodiment of the present invention.

FIGS. 9 to 13 are diagrams schematically illustrating a three-dimensional (3D) nonvolatile memory device in accordance with an embodiment of the present invention.

FIGS. 14 to 16 are diagrams schematically illustrating a 3D nonvolatile memory device in accordance with an embodiment of the present invention.

FIG. 17 is a block diagram schematically illustrating an electronic device including a semiconductor memory system in accordance with an embodiment of the present invention.

FIG. 18 is a block diagram schematically illustrating an electronic device including a semiconductor memory system in accordance with an embodiment of the present invention.

FIG. 19 is a block diagram schematically illustrating an electronic device including a semiconductor memory system in accordance with an embodiment of the present invention.

FIG. 20 is a block diagram schematically illustrating an electronic device including a semiconductor memory system in accordance with an embodiment of the present invention.

FIG. 21 is a block diagram schematically illustrating an electronic device including a semiconductor memory system in accordance with an embodiment of the present invention.

FIG. 22 is a block diagram of a data processing system including the electronic device shown in FIG. 21.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. The drawings are not necessarily to scale and, in some instances, proportions may have been exaggerated in order to clearly illustrate features of the embodiments. Throughout the disclosure, reference numerals correspond directly to the like parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. When a first layer is referred to as being “on” a second layer or “on” a substrate, it not only refers to where the first layer is formed directly on the second layer or the substrate but also to where a third layer exists between the first layer and the second layer or the substrate.

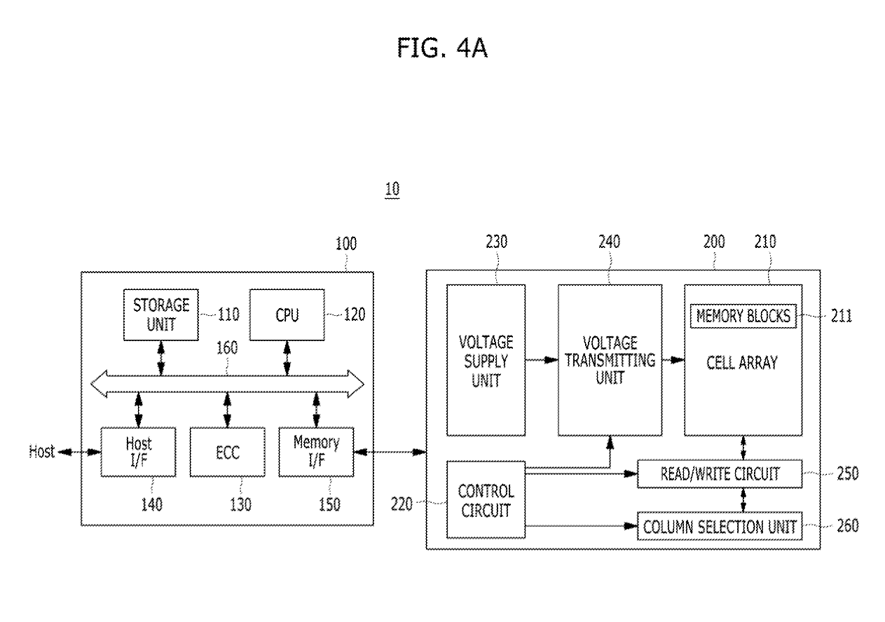

FIG. 3 is a block diagram schematically illustrating a semiconductor memory system 10 in accordance with an embodiment of the present invention.

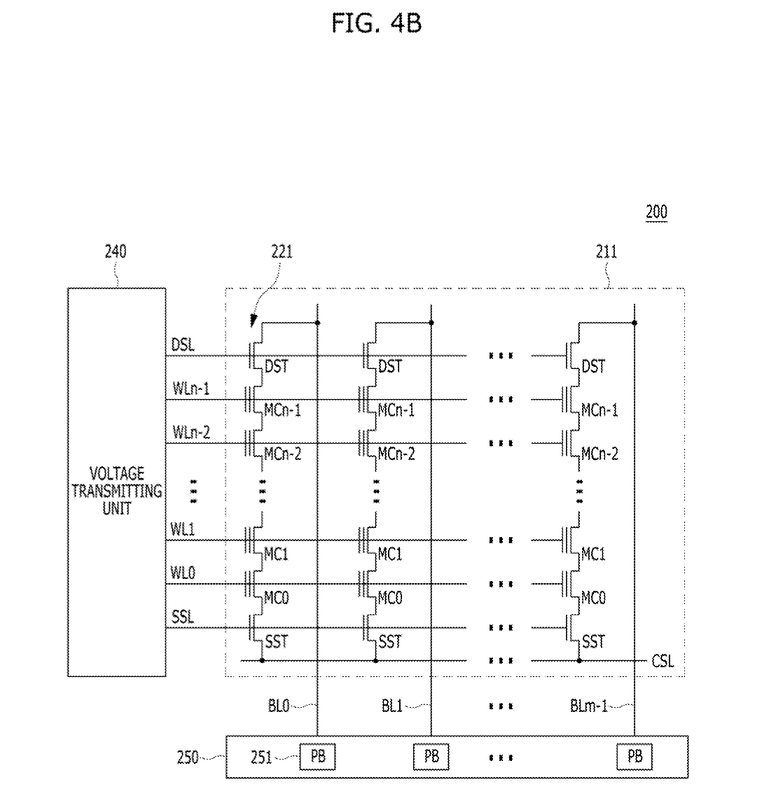

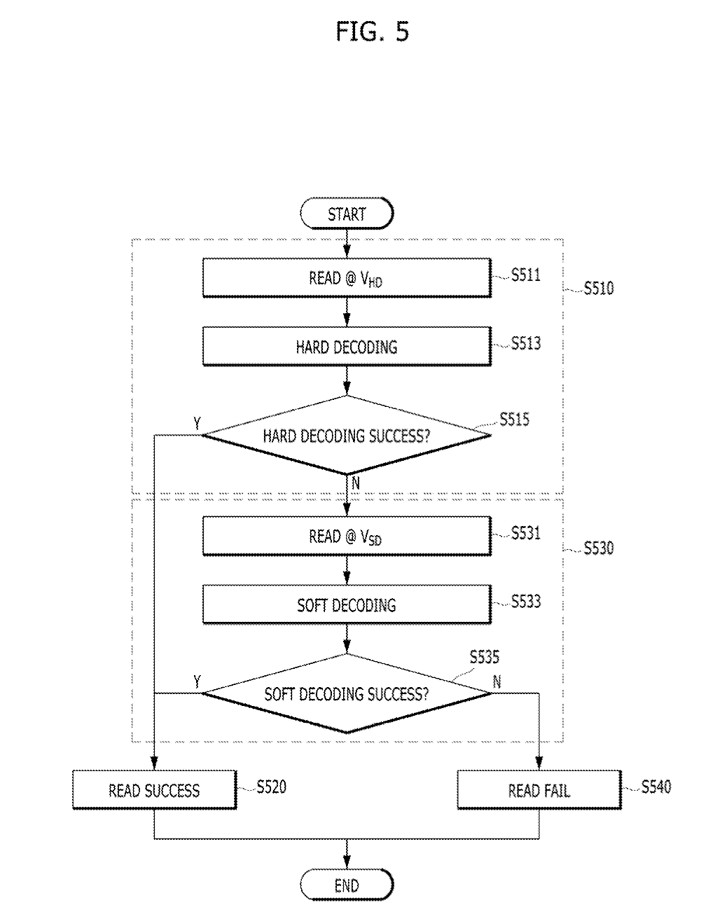

FIG. 4A is a detailed block diagram illustrating the semiconductor memory system 10 shown in FIG. 3.

FIG. 4B is a circuit diagram illustrating a memory block 211 shown in FIG. 4A.

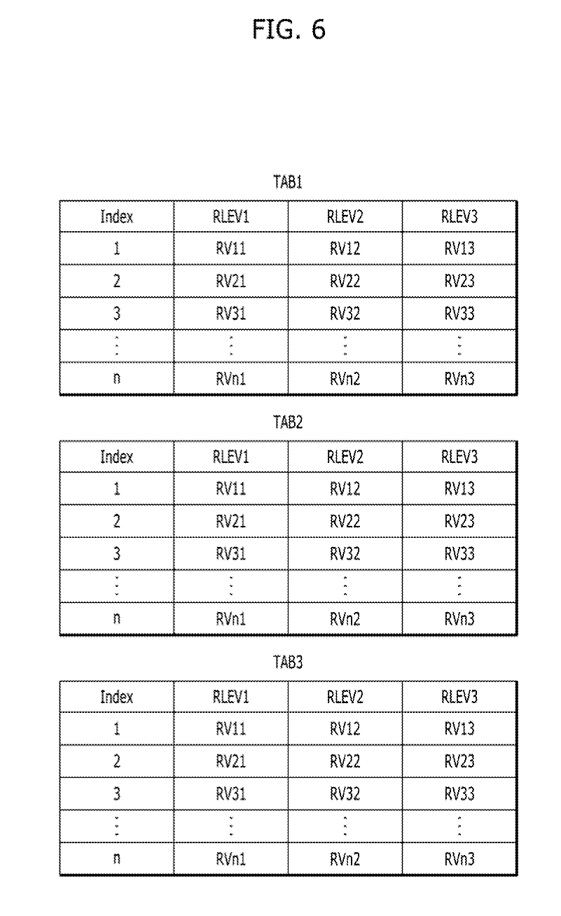

FIG. 5 is a flowchart illustrating an operation of a memory controller 100 shown in FIG. 4A.

Referring FIGS. 3 to 5, the semiconductor memory system 10 may include a semiconductor memory device 200 and the memory controller 100.

The semiconductor memory device 200 may perform one or more erase, program, and read operations under the control of the memory controller 100. The semiconductor memory device 200 may receive a command CMD, an address ADDR and data DATA through input/output lines. The semiconductor memory device 200 may receive power PWR through a power line and a control signal CTRL through a control line. The control signal may include a command latch enable (CLE) signal, an address latch enable (ALE) signal, a chip enable (CE) signal, a write enable (WE) signal, a read enable (RE) signal, and so on.

The memory controller 100 may control overall operations of the semiconductor memory device 200. The memory controller 100 may include an ECC unit 130 for correcting error bits. The ECC unit 130 may include an ECC encoder 131 and an ECC decoder 133.

The ECC encoder 131 may perform error correction encoding on data to be programmed into the semiconductor memory device 200 to output data to which parity bits are added. The parity bits may be stored in the semiconductor memory device 200.

The ECC decoder 133 may perform error correction decoding on data read from the semiconductor memory device 200. The ECC decoder 133 may determine whether the error correction decoding is successful, and may output an instruction signal based on the determination result. The ECC decoder 133 may correct error bits of data using parity bits generated by the ECC encoding.

When the number of error bits exceeds the error correction capacity of the ECC unit 130, the ECC unit 130 may not correct the error bits. In this case, the ECC unit 130 may generate an error correction fail signal.

The ECC unit 130 may correct an error through a coded modulation such as a low-density parity-check (LDPC) code, a Bose-Chaudhuri-Hocquenghem (BCH) code, a turbo code, a Reed-Solomon (RS) code, a convolution code, a Recursive Systematic Code (RSC), a Trellis-Coded Modulation (TCM), a Block Coded Modulation (BCM), and so on. The ECC unit 130 may include all circuits, systems, or devices for error correction.

In accordance with an embodiment of the present invention, the ECC unit 130 may perform an error bit correcting operation using hard read data and soft read data.

The memory controller 100 and the semiconductor memory device 200 may be integrated in a single semiconductor device. For example, the memory controller 100 and the semiconductor memory device 200 may be integrated in a single semiconductor device such as a solid-state drive (SSD). The solid state drive may include a storage device for storing data therein. When the semiconductor memory system 10 is used in an SSD, operation speed of a host (not shown) coupled to the semiconductor memory system 10 may remarkably improve.

The memory controller 100 and the semiconductor memory device 200 may be integrated in a single semiconductor device such as a memory card. For example, the memory controller 100 and the semiconductor memory device 200 may be integrated in a single semiconductor device to configure a memory card such as a PC card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and a universal flash storage (UFS).

For another example, the semiconductor memory system 10 may be provided as one of various elements comprising an electronic device such as a computer, an ultra-mobile PC (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, one of electronic devices of a home network, one of electronic devices of a computer network, one of electronic devices of a telematics network, a radio-frequency identification (RFID) device, or elements devices of a computing system.

Referring to FIG. 4A, the memory controller 100 may include a storage unit 110, a CPU 120, the ECC unit 130, a host interface 140, a memory interface 150, and a system bus 160. The storage unit 110 may operate as a working memory of the CPU 120. For example, the storage unit 110 may store a read retry table (RRT), which will be described later.

The host interface 140 may communicate with a host through one or more of various interface protocols such as a universal serial bus (USB), a multi-media card (MMC), a peripheral component interconnect express (PCI-E), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The ECC unit 130 may detect and correct an error included in the data read from the semiconductor memory device 200. The memory interface 150 may interface with the semiconductor memory device 200. The CPU 120 may perform general control operations.

The semiconductor memory device 200 may include a memory cell array 210, a control circuit 220, a voltage supply unit 230, a voltage transmitting unit 240, a read/write circuit 250, and a column selection unit 260.

The memory cell array 210 may include a plurality of memory blocks 211. User data may be stored in the memory block 211.

Referring to FIG. 4B, the memory block 211 may include a plurality of cell strings 221 coupled to bit lines BL0 to BLm−1, respectively. The cell string 221 of each column may include one or more drain selection transistors DST and one or more source selection transistors SST. A plurality of memory cells or memory cell transistors may be serially coupled between the selection transistors DST and SST. Each of the memory cells MC0 to MCn−1 may be formed of a multi-level cell (MLC) storing data information of multiple bits in each cell. The cell strings 221 may be electrically coupled to the corresponding bit lines BL0 to BLm−1, respectively.

FIG. 4B exemplarily illustrates a memory block 211 comprising a NAND-type flash memory cell. However, the memory blocks 211 of the semiconductor memory device 200 are not limited to the NAND flash memory, but may comprise NOR-type flash memory, hybrid flash memory in which two or more types of memory cells are combined, and one-NAND flash memory in which a controller is embedded inside a memory chip. Operation characteristics of the semiconductor device may be applied to a charge trap flash (CTF) in which a charge storing layer is formed by an insulating layer, as well as the flash memory device in which a charge storing layer is formed by a conductive floating gate.

Referring back to FIG. 4A, the control circuit 220 may control overall operations related to program, erase, and read operations of the semiconductor memory device 200.

The voltage supply unit 230 may provide word line voltages, for example, a program voltage, a read voltage, and a pass voltage, to the respective word lines according to an operation mode, and may provide a voltage to be supplied to a bulk, for example, a well region in which the memory cells are formed. A voltage generating operation of the voltage supply circuit 230 may be performed under control of the control circuit 220.

The voltage supply unit 230 may generate a plurality of variable read voltages for generating a plurality of read data.

The voltage transmitting unit 240 may select one of the memory blocks 211 or sectors of the memory cell array 210, and may select one of the word lines of the selected memory block under the control of the control circuit 220. The voltage transmitting unit 240 may provide the word line voltage generated from the voltage supply circuit 230 to the selected word line or non-selected word lines under the control of the control circuit 220.

The read/write circuit 250 may be controlled by the control circuit 220 and may operate as a sense amplifier or a write driver according to an operation mode. For example, during a verification/normal read operation, the read/write circuit 250 may operate as a sense amplifier for reading data from the memory cell array 210. During the normal read operation, the column selection unit 260 may output the data read from the read/write circuit 250 to the outside, for example, the memory controller 100, based on column address information. On the other hand, during the verification read operation, the read data may be provided to a pass/fail verification circuit (not illustrated) included in the semiconductor memory device 200, and be used for determining whether a program operation of the memory cell succeeds.

During the program operation, the read/write circuit 250 may operate as a write driver for driving the bit lines according to data to be stored in the memory cell array 210. During the program operation, the read/write circuit 250 may receive the data to be written in the memory cell array 210 from a buffer (not illustrated), and may drive the bit lines according to the input data. To this end, the read/write circuit 250 may include a plurality of page buffers (PB) 251 corresponding to the columns (or the bit lines) or column pairs (or bit line pairs), respectively. A plurality of latches may be included in each of the page buffers 251.

Referring to FIGS. 4A to 5, an operation of the memory controller 100 is explained in detail. The operation of the memory controller 100 may include a first ECC decoding step S510, and may additionally include a second ECC decoding step S530.

The first ECC decoding step S510 may include a step of hard decision ECC decoding data of predetermined length, which is read from a memory cell of the memory block 211 according to a hard read voltage V_{HD}. The first ECC decoding step S510 may include steps S511 to S515.

The second ECC decoding step S530 may include a step of soft decision ECC decoding the data by generating soft read data according to soft read voltages V_{SD} corresponding to a predetermined hard read voltage V_{HD}, when the hard decision ECC decoding of the first ECC decoding step S510 finally fails. The second ECC decoding step S530 may include steps S531 to S535.

At step S511, the data may be read from the semiconductor memory device 200 according to the hard read voltages V_{HD}. The memory controller 100 may provide a read command and an address to the semiconductor memory device 200. The semiconductor memory device 200 may perform a read operation on the data therefrom, corresponding to the hard read voltages V_{HD}, in response to the read command and the address. The read data may be provided to the memory controller 100.

At step S513, the hard decision ECC decoding as the first ECC decoding may be performed. The ECC unit 130 may perform the hard decision ECC decoding on the data (hereinafter “hard read data”), which is read from the semiconductor memory device 200 according to the hard read voltages V_{HD} at step S511, based on an error correction code.

At step S515, it may be determined whether the hard decision ECC decoding succeeds or fails. That is, at step S515, it may be determined whether an error of the hard read data, on which the hard decision ECC decoding is performed at step S513, is corrected. For example, the memory controller 100 may determine whether an error of the hard read data, on which the hard decision ECC decoding is performed at step S513, is corrected based on the hard read data and a parity check matrix. When a product result of the parity check matrix and the hard read data, on which the hard decision ECC decoding is performed at step S513, is a zero vector (‘0’), it may be determined that the hard read data, on which the hard decision ECC decoding is performed, is corrected. On the other hand, when the product result of the parity check matrix and the hard read data, on which the hard decision ECC decoding is performed, is not the zero vector (‘0’), it may be determined that the hard read data, on which the hard decision ECC decoding is performed, is not corrected.

When it is determined that the hard read data, on which the hard decision ECC decoding is performed, is corrected at step S515 (Y), it may be determined that the read operation according to hard read voltages V_{H}D at step S511 is successful at step S520 and the operation of the memory controller 100 may end. The hard read data, on which the hard decision ECC decoding is performed at step S513, may be the error-corrected data and may be provided to outside (e.g. to a host or external device) or used in the memory controller 100.

When it is determined that the hard read data, on which the hard decision ECC decoding is performed, is not corrected at step S515 (N), the second ECC decoding step S530 may be performed.

At step S531, the data may be read from the semiconductor memory device 200 according to the soft read voltages V_{SD}. For example, an additional read operation according to the soft read voltages V_{SD} may be performed on the memory cell, on which the first ECC decoding step S510 according to the hard read voltages V_{HD}, is performed. The soft read voltages V_{SD} may have different voltages from the hard read voltages V_{HD}.

At step S533, the soft decision ECC decoding as the second ECC decoding may be performed. The soft decision ECC decoding may be performed based on soft read data as well as the hard read data, on which the hard decision ECC decoding is performed at step S513, and the data read from the memory cell according to the soft read voltages V_{SD} at step S531. The hard read voltages V_{HD} and the soft read voltages V_{SD} may have different voltages.

For example, each of the memory cells MC0 to MCn−1 of the semiconductor memory device 200 may belong to one of the threshold voltage distributions including first to seventh program states ‘P1’ to ‘P7’ and an erase state ‘E’.

Each of the hard read voltages V_{HD} may be between two adjacent states selected from the first to seventh program states ‘P1’ to ‘P7’ and the erase state ‘E’. Each of the soft read voltages V_{SD} may be between two adjacent states selected from the first to seventh program states ‘P1’ to ‘P7’ and the erase state ‘E’, which is different from the hard read voltages V_{HD}.

The hard read data read from the memory cells MC0 to MCn−1 according to the hard read voltages V_{HD} and the soft read data read therefrom according to the soft read voltages V_{SD} may have different values from each other. For example, there may be a tailing memory cell in the memory cells MC0 to MCn−1 having a threshold voltage outside the threshold voltage distribution of a normal logic state. The hard read data read from the tailing memory cell according to the hard read voltages V_{HD} and the soft read data read therefrom according to the soft read voltages V_{SD} may have different values from each other. When the additional read operation according to the soft read voltages V_{SD} is performed subsequently to the read operation according to the hard read voltages V_{HD}, additional information on the threshold voltages of the memory cells MC0 to MCn−1, i.e., information on the tailing memory cell, may be obtained.

When the additional information is obtained, the probability of whether the data of the memory cells MC0 to MCn−1 belong to a first state, e.g., ‘1’, or a second state, e.g., ‘2’, may increase. That is, the reliability of the ECC decoding may increase. The memory controller 100 may perform the soft decision ECC decoding based on the hard read data according to the hard read voltages V_{HD} and the soft read data according to the soft read voltages V_{SD}.

At step S535, it may be determined whether the soft decision ECC decoding succeeds or fails. That is, at step S535, it may be determined whether an error of the soft read data, on which the soft decision ECC decoding is performed at step S533, is corrected. For example, the memory controller 100 may determine whether an error of the soft read data, on which the soft decision ECC decoding is performed at step S533, is corrected based on the soft read data and the parity check matrix. When a product result of the parity check matrix and the soft read data, on which the soft decision ECC decoding is performed at step S533, is the zero vector (‘0’), it may be determined that the soft read data, on which the soft decision ECC decoding is performed, is corrected. On the other hand, when the product result of the parity check matrix and the soft read data, on which the soft decision ECC decoding is performed, is not the zero vector (‘0’), it may be determined that the soft read data, on which the soft decision ECC decoding is performed, is not corrected.

The product process of the parity check matrix and the hard read data during the first ECC decoding step S510 may be substantially the same as the product process of the parity check matrix and the soft read data during the second ECC decoding step S530.

When it is determined that the soft read data, on which the soft decision ECC decoding is performed, is corrected at step S535 (Y), it may be determined that the additional read operation according to soft read voltages V_{SD} at step S531 is successful at step S520 and the operation of the memory controller 100 may end. The soft read data, on which the soft decision ECC decoding is performed at step S533, may be the error-corrected data and may be provided to the outside or used in the memory controller 100.

When it is determined that the soft read data, on which the soft decision ECC decoding is performed, is not corrected at step S535 (N), it may be determined that the read operation of the memory controller 100 on the memory cells MC0 to MCn−1 finally fails at step S540 and the operation of the memory controller 100 may end.

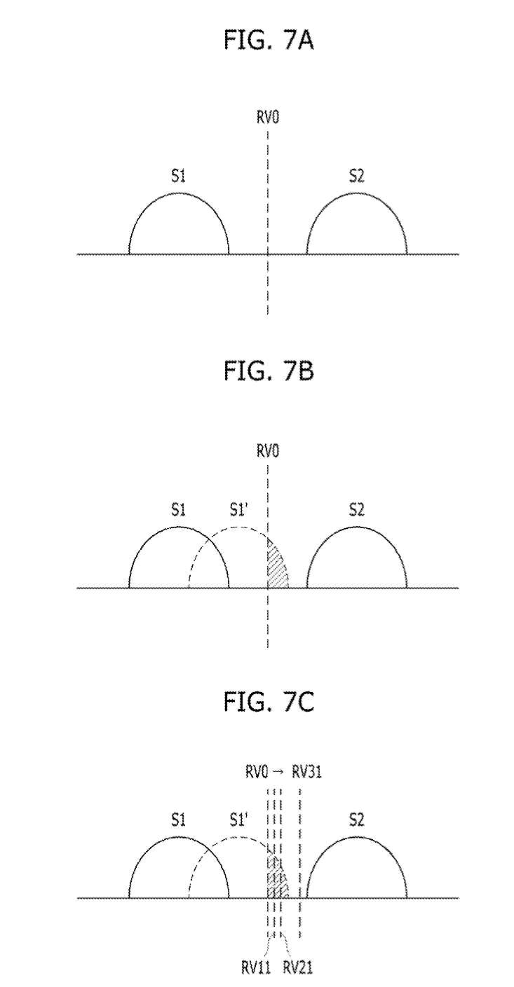

FIG. 6 is a schematic diagram illustrating read retry tables TAB1 to TAB3 included in the memory controller 100 shown in FIG. 4A.

Referring to FIG. 6, each of the read retry tables TAB1 to TAB3 may have an index representing a read environment of the semiconductor memory system 10. The read environment of the semiconductor memory system 10 may be defined as characteristics of the semiconductor memory system 10, which may affect the read operation on data programmed in the semiconductor memory device 200, such as a retention characteristic, a read disturbance characteristic, and so forth of the semiconductor memory device 200. For example, erroneous data, which is different from the programmed data, may be read from the semiconductor memory device 200 due to the retention characteristic and the read disturbance characteristic. The read retry tables TAB1 to TAB3 may be stored in the storage unit 110 of the memory controller 100.

Each of the read retry tables TAB1 to TAB3 may have n number of indexes, each of which may represent the read environment of the semiconductor memory system 10. For example, a first index “1” may represent a first state of the read disturbance characteristic and a second index “2” may represent a second state of the read disturbance characteristic. For example, an n-th index “n” may represent a first state of the retention characteristic.

Each of the read retry tables TAB1 to TAB3 may have a hard read voltage value RVij per the index, where i and j are integers greater than 0. The hard read voltage value RVij may represent a level of the hard read voltage to be applied to a page included in a selected one of the plurality of memory blocks 211 during a read retry operation on the page.

The read retry operation may be performed in the semiconductor memory device 200 when a read operation for reading programmed data in the semiconductor memory device 200 in response to an initial hard read voltage fails due to an ECC decoding fall. When the read operation with the initial hard read voltage fails since an error of the hard data read in response to the initial hard read voltage is not corrected, the read retry operation is performed with a different hard read voltage according to the hard read voltage value RVij of the read retry tables TAB1 to TAB3. The read retry operation may be performed as the hard decision ECC decoding by the ECC unit 130.

The ECC unit 130 may perform the read retry operation by sequentially changing the hard read voltage value RVij of a plurality of hard read voltage levels RLEV1 to RLEV3 included in the read retry tables TAB1 to TAB3 according to the index until the error of the hard read data is corrected.

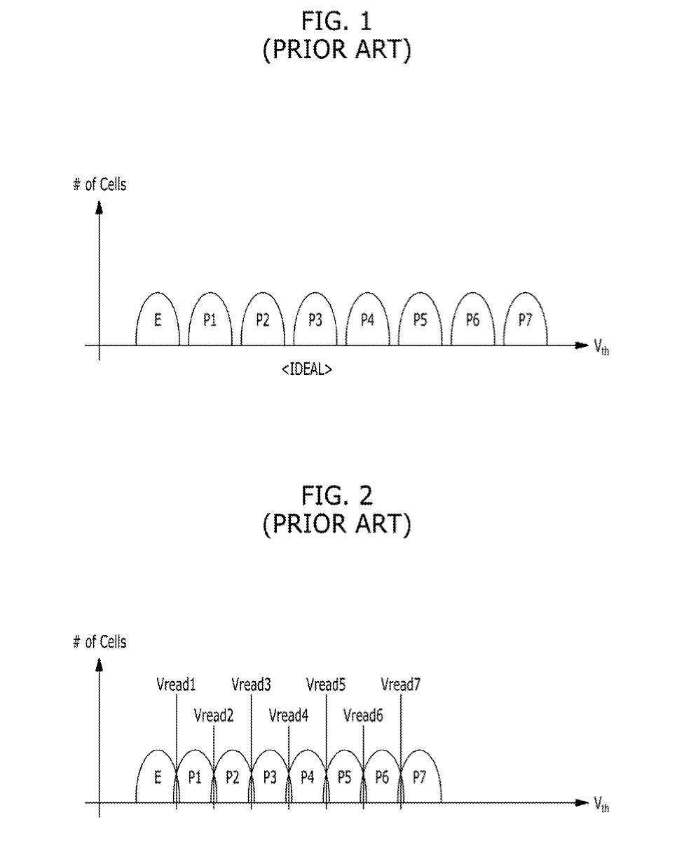

Each of the read retry tables TAB1 to TAB3 may include the plurality of hard read voltage levels RLEV1 to RLEV3 according to the threshold voltage distribution that the memory cells of the semiconductor memory device 200 may have. For example, 7 different hard read voltage levels may be required to differentiate the 8 states of the memory cell shown in FIG. 1. FIG. 6 exemplarily shows the read retry tables TAB1 to TAB3 including 3 hard read voltage levels RLEV1 to RLEV3. Also, FIG. 6 exemplarily shows 3 hard read voltage values RV11 to RV13 corresponding to the first index “1” of the plurality of hard read voltage levels RLEV1 to RLEV3.

For example, the ECC unit 130 may start the read retry operation with the 3 hard read voltage values RV11, RV12 and RV13 corresponding to the first index “1” of the first read retry table TAB1 of the read retry tables TAB1 to TAB3. When an error of the hard read data read in response to the 3 hard read voltage values RV11, RV12 and RV13 corresponding to the first index “1” of the first read retry table TAB1 is not corrected, the ECC unit 130 may perform the read retry operation again with the 3 hard read voltage values RV21, RV22 and RV23 corresponding to the next index or the second index “2” of the first read retry table TAB1. For example, the ECC unit 130 may repeatedly perform the read retry operation by sequentially changing the 3 hard read voltage values RVi1, RVi2 and RVi3 up to the n-th index “n” of the first read retry table TAB1 until the error of the hard read data is corrected.

The ECC unit 130 may select one from the read retry tables TAB1 to TAB3 in order to select the hard read voltage values RVi1, RVi2 and RVi3. As exemplarily shown in FIG. 6, when the 3 read retry tables TAB1 to TAB3 are stored in the storage unit 110, the ECC unit 130 may select one from the 3 read retry tables TAB1 to TAB3. FIG. 6 shows the read retry tables TAB1 to TAB3 including the same indication of the hard read voltage values RVi1, RVi2 and RVi3, which may be different for each of the read retry tables TAB1 to TAB3.

The read retry tables TAB1 to TAB3 may correspond to the endurance of the semiconductor memory device 200. The endurance of the semiconductor memory device 200 may correspond to program/erase cycles of the semiconductor memory device 200. For example, the first read retry table TAB1 may correspond to when the program/erase cycles of the memory block 211 included in the memory cell array 210 of the semiconductor memory device 200 are lower than 1K, the second read retry table TAB2 may correspond to when the program/erase cycles of the memory block 211 included in the memory cell array 210 of the semiconductor memory device 200 are greater than or equal to 1K and lower than 2K, and the third read retry table TAB3 may correspond to when the program/erase cycles of the memory block 211 included in the memory cell array 210 of the semiconductor memory device 200 are greater than or equal to 2K and lower than 3K. The relationship between the program/erase cycles and the read retry tables TAB1 to TAB3 may vary according to design.

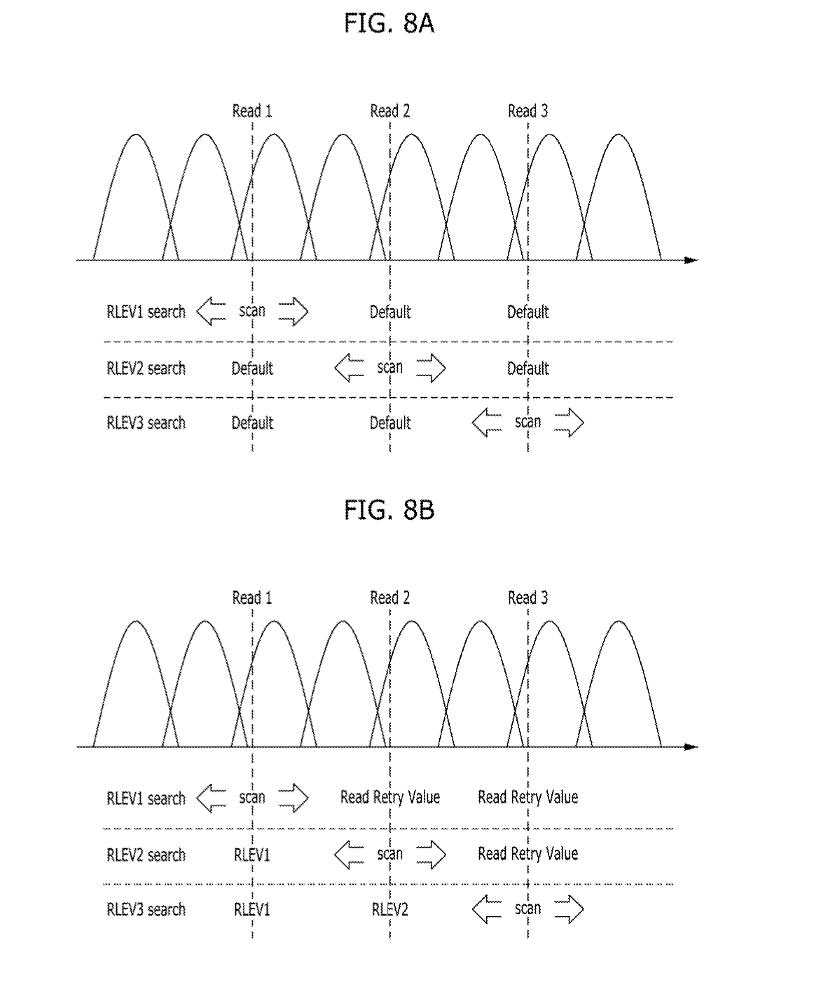

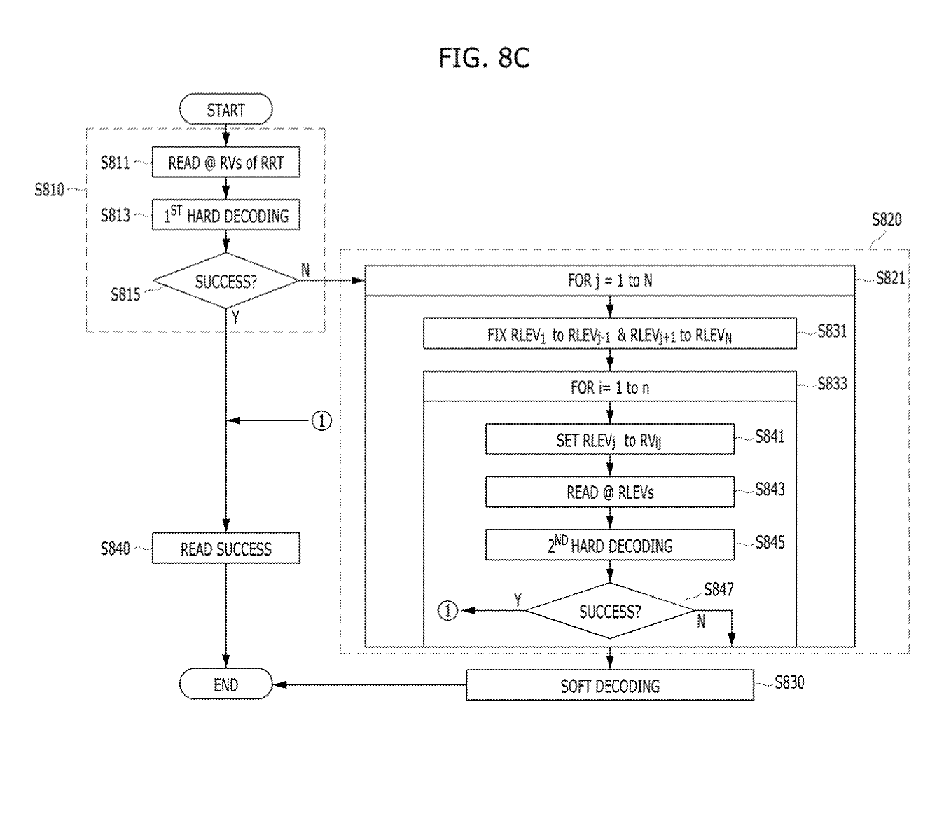

FIGS. 7A and 7B are schematic diagrams illustrating a read error, and FIG. 7C is a schematic diagram illustrating the read retry operation.

Referring to FIG. 7A, at the initial stage of the semiconductor memory device 200, 2 threshold voltage distributions S1 and S2 for the memory cells may be clearly distinguished from each other by an initial hard read voltage having a predetermined read voltage value RV0. However, as the threshold voltage distributions S1 and S2 are distorted as shown in FIG. 7B due to a change in the read environment of the semiconductor memory device 200, erroneous data may be sensed in response to the initial hard read voltage and thus a read failure may occur. Referring to FIG. 7B, when the memory cells are read according to the initial hard read voltage having the predetermined read voltage value RV0 when the first threshold voltage distribution S1 moves toward and thus overlaps with the second threshold voltage distribution S2 by the amount corresponding to a hatched portion due to a change in the read environment of the semiconductor memory device 200, the erroneous data that is substantially different than the programmed data may be sensed in the memory cells having the threshold voltages that are greater than the initial hard read voltage having the predetermined read voltage value RV0 and correspond to the hatched area of the distorted first threshold voltage distribution S1′. The sensing error may eventually cause a read failure. The change in the read environment of the semiconductor memory device 200 may be caused by the retention characteristics or a read disturbance of the flash memory.

The memory controller 100 may perform a read retry operation with the read retry tables TAB1 to TAB3 when the error of the hard read data, which is read according to the initial hard read voltage having the predetermined read voltage value RV0, is not corrected.

Referring to FIG. 7C, when the first hard read voltage level RLEV1 is the hard read voltage level for the distorted first threshold voltage distribution S1′ and the second threshold voltage distribution S2, a read failure may occur with the initial read voltage having the predetermined read voltage value RV0, as described above. When the read failure occurs even though the ECC unit 130 performs the read retry operation again by setting the first hard read voltage level RLEV1 to the read voltage value RV11 of the first index “1”, the ECC unit 130 may repeatedly perform the read retry operation by sequentially setting the first hard read voltage level RLEV1 to the hard read voltage values RV21 and RV31 of the next indexes or the second and third indexes “2” and “3”, as described above with reference to FIG. 6. FIG. 7C exemplarily shows that the error of the hard read data is corrected after the ECC unit 130 performing the read retry operation by setting the first hard read voltage level RLEV1 to the hard read voltage value RV31 of the third index “3”.

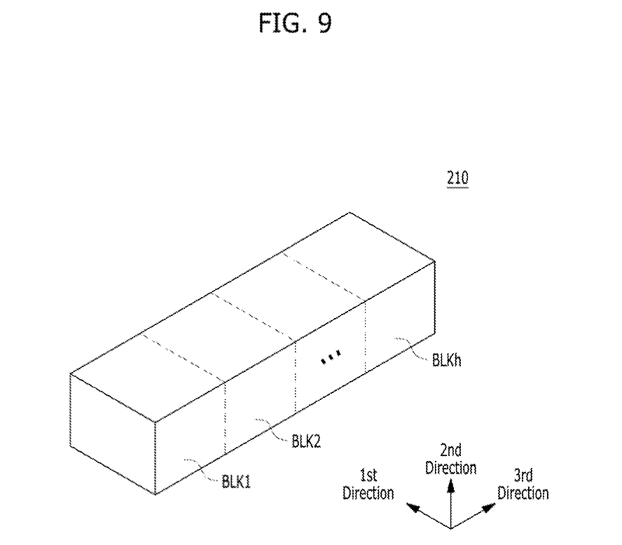

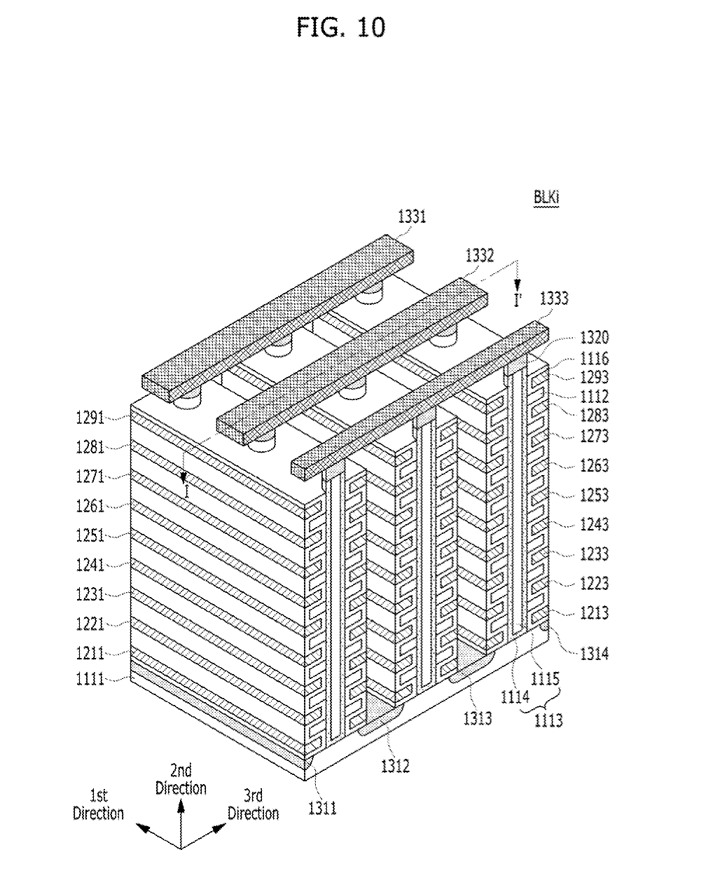

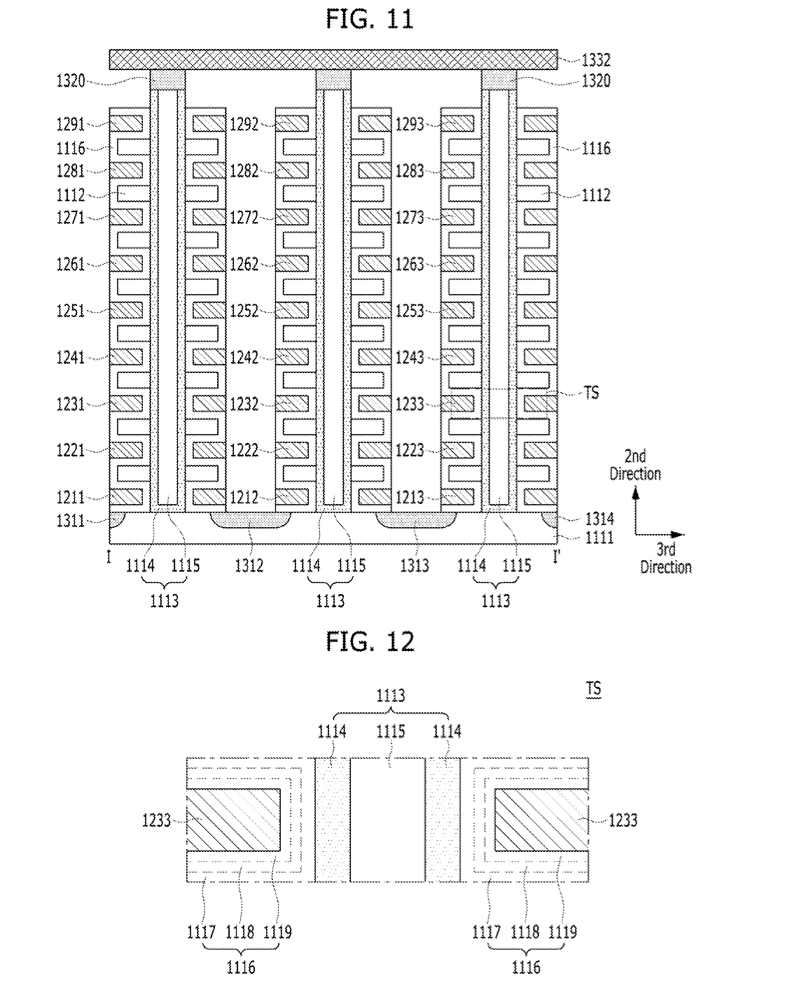

FIG. 8A is a schematic diagram illustrating an operation of determining the hard read voltage according to a comparison example.

FIG. 8B is a schematic diagram illustrating an operation of determining the hard read voltage in accordance with an exemplary embodiment of the present invention.

As described above, the memory controller 100 may perform the read retry operation with the read retry tables TAB1 to TAB3 when the error of the hard read data, which is read according to the initial hard read voltage having the predetermined read voltage value RV0, is not corrected.

During the read retry operation, the ECC unit 130 may sequentially set the plurality of hard read voltage levels RLEV1 to RLEV3 included in each of the read retry tables TAB1 to TAB3 to the hard read voltage value RVij according to the index until the error of the hard read data is corrected.

When the data read according to the hard read voltage falls in spite of the read retry operations, the ECC unit 130 may perform a scan read operation by differently changing each of the hard read voltage levels RLEV1 to RLEV3 and performing the hard decision ECC decoding operation.

According to the comparative example shown in FIG. 8A, when the ECC unit 130 differently changes each of the N number of hard read voltage levels RLEV1 to RLEVN and performs the hard decision ECC decoding operation during the scan read operation, and when the hard read voltage values assigned for each one RLEVj of the N number of hard read voltage levels RLEV1 to RLEVN are the n number of hard read voltage values RV1j to RVnj, the hard decision ECC decoding should be performed “n^{N}” times at maximum during the scan read operation. Further, according to the comparison example shown in FIG. 8A, a failure rate of the hard decision ECC decoding may be higher since the read environment of the semiconductor memory device 200 is not reflected on the hard read voltage value RVij assigned for each one RLEVj of the N number of hard read voltage levels RLEV1 to RLEVN for the scan read operation.

However, in accordance with the embodiment of the present invention as shown in FIG. 8B, for example, when the ECC unit 130 differently changes each of the N number of hard read voltage levels RLEV1 to RLEVN and performs the hard decision ECC decoding operation during the scan read operation, and when the hard read voltage values assigned for each one RLEVj of the N number of hard read voltage levels RLEV1 to RLEVN are the n number of hard read voltage values RV1j to RVnj, the ECC unit 130 may set one RLEVj of the N number of hard read voltage levels RLEV1 to RLEVN while fixing the hard read voltage value RVij of the rest RLEV1 to RLEVj−1 and RLEVj+1 to RLEVN of the N number of hard read voltage levels RLEV1 to RLEVN during setting the one RLEVj of the N number of hard read voltage levels RLEV1 to RLEVN for the hard decision ECC decoding.

Therefore, in accordance with the embodiment of the present invention, the number of operations of the hard decision ECC decoding may be reduced to “n*N” times at maximum during the scan read operation.

Further, in accordance with an embodiment of the present invention, the semiconductor memory device 200 during the scan read operation may use the hard read voltage values defined in the read retry tables TAB1 to TAB3 as the hard read voltage value RVij assigned to each one RLEVj of the N number of hard read voltage levels RLEV1 to RLEVN, which means that the read environment of the semiconductor memory device 200 is reflected on the hard read voltage value RVij assigned for each one RLEVj of the N number of hard read voltage levels RLEV1 to RLEVN for the scan read operation, and thus the failure rate of the hard decision ECC decoding may be reduced.

FIG. 8C is a flowchart illustrating an operation of the memory controller 100 in accordance with an exemplary embodiment of the present invention.

Referring to FIGS. 4A and 8C, the operation of the memory controller 100 may include a first ECC decoding step S810 using the read retry tables TAB1 to TAB3 and a second ECC decoding step S820 through the scan read operation, and may additionally include a soft decision ECC decoding step S830.

Further, the operation of the memory controller 100 may additionally include the hard decision ECC decoding according to the initial hard read voltage having the predetermined read voltage value RV0, which is described above with reference to FIGS. 6 to 7C, prior to the first ECC decoding step S810 using the read retry tables TAB1 to TAB3.

The first ECC decoding step S810 using the read retry tables TAB1 to TAB3 and the second ECC decoding step S820 through the scan read operation may correspond to the first ECC decoding step S510 described with reference to FIG. 5. The soft decision ECC decoding step S830 may correspond to the second ECC decoding step S530 described with reference to FIG. 5.

The first ECC decoding step S810 using the read retry tables TAB1 to TAB3 may include a step of the hard decision ECC decoding on data of predetermined length, which is read from a memory cell of the memory block 211 according to the N number of hard read voltage levels RLEV1 to RLEVN, each of which has the n number of hard read voltage values RV1j to RVnj defined by the read retry tables TAB1 to TAB3, as described above with reference to FIGS. 6 to 7C. The first ECC decoding step S810 may include steps S811 to S815.

The second ECC decoding step S820 through the scan read operation may include a step of the hard decision ECC decoding on the data read from the memory cell of the memory block 211 according to the N number of hard read voltage levels RLEV1 to RLEVN, one RLEVj of which is set to the n number of hard read voltage values RV1j to RVnj defined by the read retry tables TAB1 to TAB3 while fixing the hard read voltage value RVij of the other ones RLEV1 to RLEVj−1 and RLEVj+1 to RLEVN during setting the hard read voltage level RLEVj, as described above with reference to FIGS. 8A and 8B. The first ECC decoding step S810 may include steps S811 to S815.

The soft decision ECC decoding step S830 may include a step of the soft decision ECC decoding on the data by generating soft read data according to soft read voltages V_{SD} corresponding to a predetermined hard read voltage V_{HD}, when the hard decision ECC decoding of both the first ECC decoding step S810 using the read retry tables TAB1 to TAB3 and the second ECC decoding step S820 through the scan read operation finally fails. The second ECC decoding step S530 may include steps S531 to S535.

At step S811 of the first ECC decoding step S810 using the read retry tables TAB1 to TAB3, data may be read from a memory cell of the memory block 211 according to the N number of hard read voltage levels RLEV1 to RLEVN, each of which has the n number of hard read voltage values RV1j to RVnj defined by the read retry tables TAB1 to TAB3, as described above with reference to FIGS. 6 to 7C. The memory controller 100 may transmit a read command and an address to the semiconductor memory device 200. In response to the read command and the address, the memory controller 100 may perform a read operation on data from the semiconductor memory device 200 according to the N number of hard read voltage levels RLEV1 to RLEVN, each of which has the n number of hard read voltage values RV1j to RVnj defined by the read retry tables TAB1 to TAB3. The read data may be sent to the memory controller 100.

At step S813, the hard decision ECC decoding as the first hard ECC decoding may be performed. The ECC unit 130 may perform the hard decision ECC decoding on the hard read data using the error correction code. The hard read data may be read from the semiconductor memory device 200 according to the n number of hard read voltage values RV1j to RVnj for each RLEVj of the N number of hard read voltage levels RLEV1 to RLEVN defined by the read retry tables TAB1 to TAB3.

At step S815, it may be determined whether the hard decision ECC decoding succeeds or fails. That is, at step S815, it may be determined whether an error of the hard read data, on which the hard decision ECC decoding is performed at step S813, is corrected. For example, the memory controller 100 may determine whether an error of the hard read data, on which the hard decision ECC decoding is performed at step S813, is corrected based on the hard read data and a parity check matrix. When a product result of the parity check matrix and the hard read data, on which the hard decision ECC decoding is performed at step S813, is a zero vector (‘0’), it may be determined that the hard read data, on which the hard decision ECC decoding is performed, is corrected. On the other hand, when the product result of the parity check matrix and the hard read data, on which the hard decision ECC decoding is performed, is not the zero vector (‘0’), it may be determined that the hard read data, on which the hard decision ECC decoding is performed, is not corrected.

When it is determined that the hard read data, on which the hard decision ECC decoding is performed, is corrected at step S815 (Y), it may be determined at step S840 that the read operation according to the n number of hard read voltage values RV1j to RVnj for each RLEVj of the N number of hard read voltage levels RLEV1 to RLEVN defined by the read retry tables TAB1 to TAB3 at step S811 is successful and the operation of the memory controller 100 may end. The hard read data, on which the hard decision ECC decoding is performed at step S813, may be the error-corrected data and may be provided to outside (e.g. to a host or external device) or used in the memory controller 100.

When it is determined that the hard read data, on which the hard decision ECC decoding is performed, is not corrected at step S815 (N), the second ECC decoding step S820 may be performed.

As described with reference to FIG. 6, the ECC unit 130 may perform the read retry operation by sequentially changing the hard read voltage value RVij included in each of the N number of hard read voltage levels RLEV1 to RLEVN in each of the read retry tables TAB1 to TAB3 according to the index until the error of the hard read data is corrected. For example, when an error of the hard read data read in response to the 3 hard read voltage values RV11, RV12 and RV13 corresponding to the first index “1” of the first read retry table TAB1 is not corrected, the ECC unit 130 may perform the read retry operation again with the 3 hard read voltage values RV21, RV22 and RV23 corresponding to the next index or the second index “2” of the first read retry table TAB1. For example, the ECC unit 130 may repeatedly perform the read retry operation by sequentially changing the 3 hard read voltage values RVi1, RVi2 and RVi3 up to the n-th index “n” of the first read retry table TAB1 until the error of the hard read data is corrected. For example, the second ECC decoding step S820 through the scan read operation S820 may be performed when it is determined at step S815 that the hard read data, on which the hard decision ECC decoding of step S813 is performed, is not corrected even though the ECC unit 130 sequentially performs the read retry operation according to 3 hard read voltage values RVi1, RVi2 and RVi3 from the first index “1” to the n-th index “n” of the first read retry table TAB1.

Step S821 during the second ECC decoding step S820 through the scan read operation may be sequentially performed according to each of the N number of hard read voltage levels RLEV1 to RLEVN. That is, step S821 may be sequentially performed going from the first hard read voltage level RLEV1 to the N-th hard read voltage level RLEVN of the N number of hard read voltage levels RLEV1 to RLEVN.

At step S831 during step 821, the memory controller 100 may fix the hard read voltage value RVij of the other ones RLEV1 to RLEVj−1 and RLEVj+1 to RLEVN except for a current one RLEVj of the N number of hard read voltage levels RLEV1 to RLEVN. The fixed hard read voltage value RVij may be the one corresponding to a predetermined index of each of the other ones RLEV1 to RLEVj−1 and RLEVj+1 to RLEVN defined by the read retry tables TAB1 to TAB3.

Next, step S833 during step S821 may be sequentially performed according to the n number of hard read voltage values RV1j to RVnj corresponding to the first index “1” to the n-th index “n” of the read retry tables TAB1 to TAB3 for the current hard read voltage level RLEVj. That is, step S833 may be sequentially performed going from the first hard read voltage value RV1j corresponding to the first index “1” to the nth hard read voltage RVnj corresponding to the n-th index “n” of the read retry tables TAB1 to TAB3 for the current hard read voltage level RLEVj.

At step S841 during step S833, the memory controller 100 may set the current hard read voltage level RLEVj to the hard read voltage value RVij corresponding to the i-th index “i” of the read retry tables TAB1 to TAB3.

Next at S843 during step S833, data stored in the semiconductor memory device 200 may be read according to the current hard read voltage level RLEVj, which is set at step S841 to the hard read voltage value RVij corresponding to the i-th index “i” of the read retry tables TAB1 to TAB3, and the other ones RLEV1 to RLEVj−1 and RLEVj+1 to RLEVN, which is fixed at step S831 to the hard read voltage value RVij corresponding to the predetermined index of the read retry tables TAB1 to TAB3. The hard read data, which is read at step S843, may be provided to the memory controller 100.

Next, at step S845 during step S833, the hard decision ECC decoding as the second hard ECC decoding may be performed. The ECC unit 130 may perform the hard decision ECC decoding on the hard read data, which is read at step S843, using the error correction code.

At step S847 during step S833, it may be determined whether the hard decision ECC decoding succeeds or fails. That is, at step S847, it may be determined whether an error of the hard read data, on which the hard decision ECC decoding is performed at step S845, is corrected. For example, the memory controller 100 may determine whether an error of the hard read data, on which the hard decision ECC decoding is performed at step S813, is corrected based on the hard read data and a parity check matrix. For example, when a product result of the parity check matrix and the hard read data, on which the hard decision ECC decoding is performed at step S845, is a zero vector (‘0’), it may be determined that the hard read data, on which the hard decision ECC decoding is performed, is corrected. On the other hand, when the product result of the parity check matrix and the hard read data, on which the hard decision ECC decoding is performed, is not the zero vector (‘0’), it may be determined that the hard read data, on which the hard decision ECC decoding is performed, is not corrected.

When it is determined that the hard read data, on which the hard decision ECC decoding is performed, is corrected at step S847 (Y), it may be determined that the read operation according to hard read voltage at step S847 is successful at step S840 and the operation of the memory controller 100 may end.

When it is determined that the hard read data, on which the hard decision ECC decoding is performed, is not corrected at step S847 (N), the memory controller 100 may set the current hard read voltage level RLEVj of step S841 to the hard read voltage value RVij corresponding to the next index “i+1” of the read retry tables TAB1 to TAB3. With the current hard read voltage level RLEVj set to the hard read voltage value RVij corresponding to the next index “i+1”, steps S841 to S847 may be repeated. Such repetition may last until the current hard read voltage level RLEVj set to the hard read voltage value RVij corresponds to the last index “n” of the read retry tables TAB1 to TAB3.

Also, when it is determined that the hard read data, to which the hard decision ECC decoding is performed even with the current hard read voltage level RLEVj set to the hard read voltage value RVij corresponding to the last index “n” of the read retry tables TAB1 to TAB3, is not corrected at step S847 (N), the memory controller 100 may repeat steps S831 and S833 with the next one RLEVj+1 of the N number of hard read voltage levels RLEV1 to RLEVN. Such repetition may last until the last one RLEVN of the N number of hard read voltage levels RLEV1 to RLEVN.

When it is determined that the hard read data, on which the hard decision ECC decoding is performed even with the last one RLEVN of the N number of hard read voltage levels RLEV1 to RLEVN, is not corrected at step S847 (N), it may be determined that the hard decision ECC decoding finally fails and the memory controller 100 may perform the soft decision ECC decoding of step S830. The soft decision ECC decoding of step S830 may correspond to the second ECC decoding step S530, which is described with reference to FIG. 5.

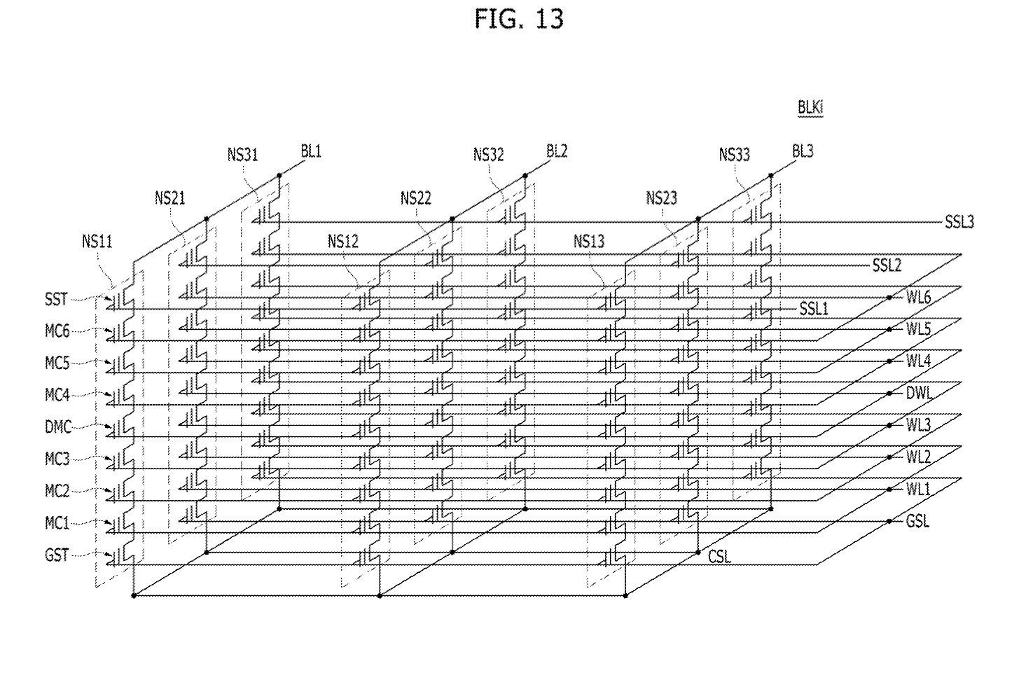

FIG. 9 is a block diagram of the memory cell array 210 shown in FIG. 4B.

Referring to FIG. 9, the memory cell array 210 may include a plurality of memory blocks BLK1 to BLKh. Each of the memory blocks BLK1 to BLKh may have a 3D structure or a vertical structure. For example, each of the memory blocks BLK1 to BLKh may include a structure extending along first to third directions.

Each of the memory blocks BLK1 to BLKh may include a plurality of NAND strings NS extending along the second direction. A plurality of NAND strings NS may be provided along the first and third directions. Each of the NAND strings NS may be coupled to a bit line BL, one or more string select lines SSL, one or more ground select lines GSL, a plurality of word lines WL, one or more dummy word lines DWL, and a common source line CSL. That is, each of the memory blocks BLK1 to BLKh may be coupled to a plurality of bit lines BL, a plurality of string select lines SSL, a plurality of ground select lines GSL, a plurality of word lines WL, a plurality of dummy word lines DWL, and a plurality of common source lines CSL.

FIG. 10 is a perspective view of one memory block BLKi of the memory blocks BLK1 to BLKh shown in FIG. 9. FIG. 11 is a cross-sectional view taken along a line I-I′ of the memory block BLKi shown in FIG. 10.

Referring to FIGS. 10 and 11, the memory block BLKi may include a structure extending along first to third directions.

A substrate 1111 may be provided. For example, the substrate 1111 may include a silicon material doped by a first type impurity. For example, the substrate 1111 may include a silicon material doped by a p-type impurity or a p-type well, e.g., a pocket p-well. The substrate 1111 may further include an n-type well surrounding the p-type well. In the description, it is exemplarily assumed that the substrate 1111 is p-type silicon. However, the substrate 1111 is not limited to p-type silicon.

A plurality of doping regions 1311 to 1314 extending along the first direction may be provided over the substrate 1111. For example, the plurality of doping regions 1311 to 1314 may have a second type impurity differing from that of the substrate 1111. For example, the plurality of doping regions 1311 to 1314 may be doped with an n-type impurity. In the description, it is exemplarily assumed that the first to fourth doping regions 1311 to 1314 are n-type. However, the first to fourth doping regions 1311 to 1314 are not limited to n-type.

A plurality of insulation materials 1112 extending along the first direction may be sequentially provided along the second direction over a region of the substrate 1111 between the first and second doping regions 1311 and 1312. For example, the insulation materials 1112 and the substrate 1111 may be spaced apart by a predetermined distance in the second direction. In a second example, the insulation materials 1112 may be spaced apart from each other in the second direction. In a third example, the insulation materials 1112 may include an insulator such as silicon oxide.

A plurality of pillars 1113 may be sequentially provided along the first direction over a region of the substrate 111 between the first doping region 1311 and the second doping region 1312, and may be formed to penetrate the insulation materials 1112 along the second direction. For example, each of the pillars 1113 may penetrate the insulation materials 1112 to contact the substrate 1111. For example, each of the pillars 1113 may be composed of a plurality of materials. A surface layer 1114 of each of the pillars 1113 may include a silicon material having a first type of impurity. The surface layer 1114 of each of the pillars 1113 may include a silicon material doped with the same type impurity as that of the substrate 1111. In the description, it is exemplarily assumed that the surface layer 1114 of each of the pillars 1113 includes p-type silicon. However, the surface layer 1114 of each of pillars 1113 is not limited to being p-type silicon.

An inner layer 1115 of each of the pillars 1113 may be formed of an insulation material. For example, the inner layer 1115 of each of the pillars 1113 may be filled with an insulation material such as silicon oxide.

In a region between the first and second doping regions 1311 and 1312, an insulation layer 1116 may be provided along exposed surfaces of the insulation materials 1112, the pillars 1113, and the substrate 1111. For example, the thickness of the insulation layer 1116 may be less than half of the distance between the insulation materials 1112. That is, a region in which a material other than the insulation materials 1112 and the insulation layer 1116 is disposed may be provided between (i) the insulation layer 1116 provided over the bottom surface of a first insulation material of the insulation materials 1112 and (ii) the insulation layer 1116 provided over the top surface of a second insulation material of the insulation materials 1112. The first insulation material of the insulation materials 1112 may be disposed over the second insulation material of the insulation materials 1112.

In the region between the first and second doping regions 1311 and 1312, conductive materials 1211 to 1291 may be provided over the surface of the insulation layer 1116. For example, the conductive material 1211 extending along the first direction may be provided between the substrate 1111 and the insulation materials 1112 adjacent to the substrate 1111. More specifically, the conductive material 1211 extending along the first direction may be provided between (i) the insulation layer 1116 disposed at the bottom surface of the insulation materials 1112 adjacent to the substrate 1111 and (ii) the insulation layer 1116 disposed over the substrate 1111.

A conductive material extending along the first direction may be provided between (i) the insulation layer 1116 disposed at the top surface of a first specific insulation material among the insulation materials 1112 and (ii) the insulation layer 1116 disposed at the bottom surface of a second specific insulation material among the insulation materials 1112, which is disposed over the first specific insulation material 1112. For example, a plurality of conductive materials 1221 to 1281 extending along the first direction may be provided between the insulation materials 1112. Also, a conductive material 1291 extending along the first direction may be provided over the uppermost insulation materials 1112. For example, the conductive materials 1211 to 1291 extending along the first direction may be a metallic material. In another example, the conductive materials 1211 to 1291 extending along the first direction may be a conductive material such as polysilicon.

The same structure as the structure disposed between the first and second doping regions 1311 and 1312 may be provided between the second and third doping regions 1312 and 1313. For example, the insulation materials 1112 extending along the first direction, the pillars 1113 which are sequentially arranged in the first direction and penetrate the insulation materials 1112 along the second direction, the insulation layer 1116 provided over the surfaces of the insulation materials 1112 and the pillars 1113, and the conductive materials 1212 to 1292 extending along the first direction may be provided between the second and third doping regions 1312 and 1313.

The same structure as disposed between the first and second doping regions 1311 and 1312 may be provided between the third and fourth doping regions 1313 and 1314. For example, the insulation materials 1112 extending along the first direction, the pillars 1113 which are sequentially arranged in the first direction and penetrate the insulation materials 1112 along the second direction, the insulation layer 1116 provided over the surfaces of the insulation materials 1112 and the pillars 1113, and the conductive materials 1213 to 1293 extending along the first direction may be provided between the third and fourth doping regions 1313 and 1314.

Drains 1320 may be provided over the pillars 1113, respectively. For example, the drains 1320 may be a silicon material doped with a second type material. For example, the drains 1320 may be a silicon material doped with an n-type material. In the description, it is exemplarily assumed that the drains 320 are a silicon material doped with an n-type material. However, the drains 320 are not limited to being n-type silicon materials. For example, the width of the drains 1320 may be wider than that of their corresponding pillars 1113. For example, the drains 1320 may be provided over a top surface of their corresponding pillars 1113, in a pad shape.

Conductive materials 1331 to 1333 extending in the third direction may be provided over the drains 1320. The conductive materials 1331 to 1333 may be sequentially disposed along the first direction. The conductive materials 1331 to 1333 may be respectively coupled to the drains 1320 in the corresponding region. For example, the drains 1320 and the conductive material 1333 extending along the third direction may be coupled to each other through contact plugs, respectively. For example, the conductive materials 1331 to 1333 extending along the third direction may be a metallic material. In another example, the conductive materials 1331 to 1333 may be a conductive material such as polysilicon.

Referring to FIGS. 10 and 11, each of the pillars 1113 may be coupled to the insulation layer 1116 and the conductive materials 1211 to 1291, 1212 to 1292, and 1213 to 1293 extending along the first direction, to form a string. For example, each of the pillars 1113 may form a NAND string NS together with the insulation layer 1116 and the conductive materials 1211 to 1291, 1212 to 1292, and 1213 to 1293 extending along the first direction. The NAND string NS may include a plurality of transistor structures TS.

FIG. 12 is a cross-sectional view of the transistor structure TS shown in FIG. 11.

Referring to FIGS. 10 to 12, the insulation layer 1116 may include first to third sub insulation layers 1117, 1118 and 1119.

The surface layer 1114 of P-type silicon in each of the pillars 1113 may serve as a body. The first sub insulation layer 1117, adjacent to each of the pillars 1113, may serve as a tunneling insulation layer. For example, the first sub insulation layer 1117, adjacent to the each of the pillars 1113, may include a thermal oxide layer.

The second sub insulation layer 1118 may serve as a charge storage layer. For example, the second sub insulation layer 1118 may serve as a charge trap layer. The second sub insulation layer 1118 may include a nitride layer or a metal oxide layer, e.g., aluminium oxide layer, hafnium oxide layer, etc.

The third sub insulation layer 1119, adjacent to a conductive material 1233, may serve as a blocking insulation layer. For example, the third sub insulation layer 1119, adjacent to the conductive material 1233 extending along the first direction, may have a mono-layered or multi-layered structure. The third sub insulation layer 1119 may be a high dielectric layer, e.g., aluminium oxide layer, hafnium oxide layer, etc., having a dielectric constant greater than the first and second sub insulation layers 1117 and 1118.

The conductive material 1233 may serve as a gate or control gate. That is, the gate or control gate 1233, the blocking insulation layer 1119, the charge trap layer 1118, the tunneling insulation layer 1117, and the body 1114 may form a transistor or memory cell transistor structure. For example, the first to third sub insulation layers 1117 to 1119 may form an oxide-nitride-oxide (ONO) structure. The surface layer 1114 of p-type silicon in each of the pillars 1113 may be a body extending in the second direction.

The memory block BLKi may include the plurality of pillars 1113. That is, the memory block BLKi may include the plurality of NAND strings NS. More specifically, the memory block BLKi may include the plurality of NAND strings NS extending along the second direction or a direction perpendicular to the substrate 1111.

Each of the NAND strings NS may include the plurality of transistor structures TS, which are stacked in the second direction. One or more of the plurality of transistor structures TS of each NAND string NS may serve as a string select transistor SST. One or more of the plurality of transistor structures TS of each NAND string may serve as a ground select transistor GST.

The gates or control gates may correspond to the conductive materials 1211 to 1291, 1212 to 1292, and 1213 to 1293 extending along the first direction. That is, the gates or control gates may extend along the first direction to form word lines WL and two or more select lines, e.g., one or more string select lines SSL and one or more ground select lines GSL.

The conductive materials 1331 to 1333 extending along the third direction may be coupled to one end of the NAND strings NS. For example, the conductive materials 1331 to 1333 extending along the third direction may serve as bit lines BL. That is, in one memory block BLKi, a single bit line BL may be coupled to the plurality of NAND strings.

The second type doping regions 1311 to 1314 extending along the first direction may be coupled to the other end of the NAND strings NS. The second type doping regions 1311 to 1314 extending along the first direction may serve as common source lines CSL.

In summary, the memory block BLKi may include the plurality of NAND strings NS extending along a direction, e.g., a second direction, perpendicular to the substrate 1111, and may operate as a NAND flash memory block, for example, a charge trap type memory, in which the plurality of NAND strings NS is coupled to a single bit line BL.

With reference to FIGS. 10 to 12, the conductive materials 1211 to 1291, 1212 to 1292, and 1213 to 1293 extending along the first direction are provided on 9 layers. However, the first conductive materials 1211 to 1291, 1212 to 1292, and 1213 to 1293 extending along the first direction are not limited to 9 layers. For example, the conductive materials extending along the first direction may be provided upon 8, 16, or more layers. That is, a NAND string may include 8, 16, or more transistors.

With reference to FIGS. 10 to 12, 3 NAND strings NS are coupled to a single bit line BL. However, the embodiment is not limited to 3 NAND strings NS coupled to a single bit line BL. In another embodiment, in the memory block BLKi, m NAND strings NS may be coupled to a single bit line BL, m being an integer. The number of the conductive materials 1211 to 1291, 1212 to 1292, and 1213 to 1293 extending along the first direction and the number of common source lines 1311 to 1314 may also be adjusted to correspond to the number of NAND strings NS coupled to a single bit line BL.

With reference to FIGS. 10 to 12, 3 NAND strings NS are coupled to a single conductive material extending along the first direction. However, the embodiment is not limited to 3 NAND strings NS coupled to a single conductive material. In another embodiment, n NAND strings NS may be coupled to a single conductive material, n being an integer. The number of the conductive materials 1331 to 1333 extending along the third direction may also be adjusted to correspond to the number of NAND strings NS coupled to a single conductive material.

FIG. 13 is an equivalent circuit diagram illustrating the memory block BLKi described with reference to FIGS. 10 to 12.

Referring to FIGS. 10 to 13, NAND strings NS11 to NS31 may be provided between a first bit line BL1 and a common source line CSL. The first bit line BL1 may correspond to the conductive material 1331 extending along the third direction. NAND strings NS12 to NS32 may be provided between a second bit line BL2 and the common source line CSL. The second bit line BL2 may correspond to the conductive material 1332 extending along the third direction. NAND strings NS13 to NS33 may be provided between a third bit line BL3 and the common source line CSL. The third bit line BL3 may correspond to the conductive material 1333 extending along the third direction.

A string select transistor SST of each NAND string NS may be coupled to a corresponding bit line BL. A ground select transistor GST of each NAND string NS may be coupled to the common source line CSL. Memory cells MC may be provided between the string select transistor SST and the ground select transistor GST of each NAND string NS.

The NAND strings NS may be defined in units of rows and columns. The NAND strings NS commonly coupled to a single bit line may form a single column. For example, the NAND strings NS11 to NS31 coupled to the first bit line BL1 may correspond to a first column. The NAND strings NS12 to NS32 coupled to the second bit line BL2 may correspond to a second column. The NAND strings NS13 to NS33 coupled to the third bit line BL3 may correspond to a third column.

The NAND strings NS coupled to a single string select line SSL may form a single row. For example, the NAND strings NS11 to NS13 coupled to a first string select line SSL1 may form a first row. The NAND strings NS21 to NS23 coupled to a second string select line SSL2 may form a second row. The NAND strings NS31 to NS33 coupled to a third string select line SSL3 may form a third row.

A height may be defined for each NAND string NS. For example, the height of the ground select transistor GST may be defined as a value ‘1’ in each NAND string NS. In each NAND string NS, the closer to the string selection transistor SST, the higher the height of the memory cell, when measured from the substrate 1111. In each NAND string NS, the height of the memory cell MC6 adjacent to the string select transistor SST may be defined as a value ‘8’, which is 8 times greater than the ground select transistor GST.

The string select transistors SST of the NAND strings NS of the same row may share the same string select line SSL. The string select transistors SST of the NAND strings NS in different rows may be coupled with different string select lines SSL1, SSL2, and SSL3, respectively.

The memory cells MC having the same height in the NAND strings NS of the same row may share a word line WL. At a predetermined height, the word line WL may be shared by the memory cells MC of the NAND strings NS in different rows but in the same level or at the same height. At a predetermined height or at the same level, dummy memory cells DMC of the NAND strings NS of the same row may share a dummy word line DWL. At a predetermined height or level, the dummy memory cells DMC of the NAND strings NS in different rows may share the dummy word lines DWL.

For example, the word lines WL or the dummy word lines DWL located at the same level or height or layer may be commonly coupled on layers where the conductive materials 1211 to 1291, 1212 to 1292, and 1213 to 1293 extending in the first direction are provided. For example, the conductive materials 1211 to 1291, 1212 to 1292, and 1213 to 1293 provided at a given level or height or layer may be coupled to an upper layer via a contact. The conductive materials 1211 to 1291, 1212 to 1292, and 1213 to 1293 extending in the first direction may be coupled in common at the upper layer. The ground select transistors GST of the NAND strings NS of the same row may share the ground select line GSL. The ground select transistors GST of the NAND strings NS in different rows may share the ground select line GSL. That is, the NAND strings NS11 to NS13, NS21 to NS23, and NS31 to NS33 may be coupled in common to the ground select line GSL.

The common source line CSL may be coupled to the NAND strings NS. For example, the first to fourth doping regions 1311 to 1314 may be coupled at an active region of the substrate 1111. For example, the first to fourth doping regions 1311 to 1314 may be coupled to an upper layer via a contact. The first to fourth doping regions 1311 to 1314 may be coupled in common at the upper layer.

As illustrated in FIG. 13, the word lines WL at the same height or level may be commonly coupled. Therefore, when a word line WL at a specific height is selected, all of the NAND strings NS coupled to the selected word line WL may be selected. The NAND strings NS in different rows may be coupled to different string select lines SSL. Accordingly, among the NAND strings NS coupled to the same word line WL, the NAND strings NS of the unselected row may be electrically isolated from the bit lines BL1 to BL3 according to the selection of the string selection lines SSL1 to SSL3. That is, a row of the NAND strings NS may be selected by selecting one of the string select lines SSL1 to SSL3. The NAND strings NS of the selected row may be selected in units of columns according to selection of the bit lines BL1 to BL3.

In each NAND string NS, a dummy memory cell DMC may be provided. FIG. 13 shows the dummy memory cell DMC provided between the third memory cell MC3 and the fourth memory cell MC4 in each NAND string NS. That is, the first to third memory cells MC1 to MC3 may be provided between the dummy memory cell DMC and the ground select transistor GST. The fourth to sixth memory cells MC4 to MC6 may be provided between the dummy memory cell DMC and the string select transistor SST. In the embodiment, it is exemplarily assumed that the memory cells MC in each NAND string NS are divided into memory cell groups by the dummy memory cell DMC. A memory cell group, e.g., MC1 to MC3, that is adjacent to the ground select transistor GST among the memory cell groups may be referred to as a lower memory cell group. A memory cell group, e.g., MC4 to MC6, adjacent to the string select transistor SST among the memory cell groups may be referred to as an upper memory cell group.

An operating method of a nonvolatile memory device that includes one or more cell strings each arranged in a direction perpendicular to a substrate and coupled with a memory controller, a string select transistor, and a ground select transistor will be described with reference to FIGS. 9 to 13. With the operating method, the nonvolatile memory device may: be provided with a first read command to perform first and second hard decision read operations according to a first hard read voltage and a second hard read voltage, which is different from the first hard read voltage; acquire hard read data; select one of the first and second hard decision voltages based on an error bit state of the hard read data; acquire soft read data according to a soft read voltage, which is different from the first and second hard decision read voltages; and provide the soft read data to a memory controller.

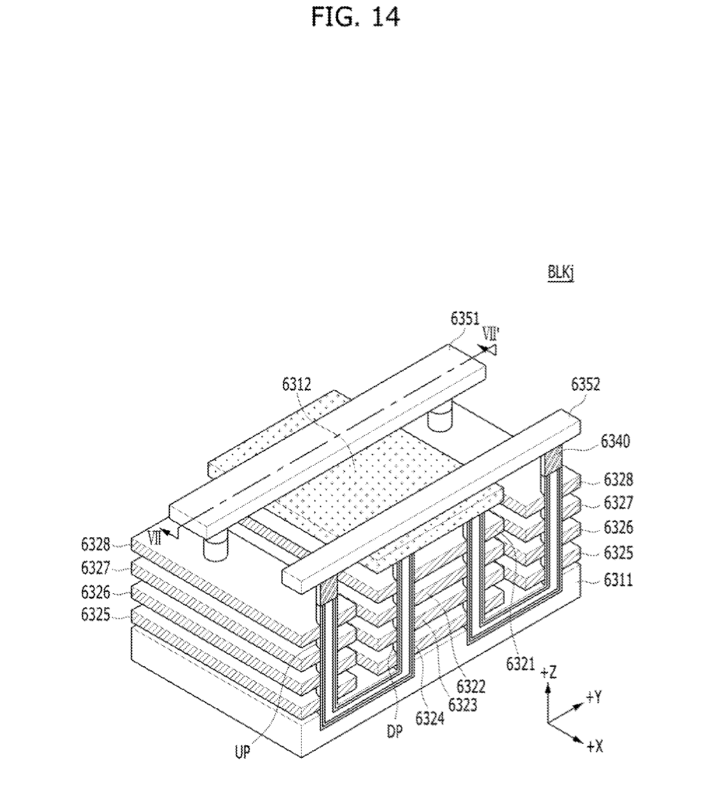

FIGS. 14 to 16 are diagrams schematically illustrating a 3D nonvolatile memory device in accordance with an embodiment of the present invention. FIGS. 14 to 16 illustrate the semiconductor memory device, for example, a flash memory device implemented in 3D in accordance with an embodiment of the present invention.

FIG. 14 is a perspective view illustrating one memory block BLKj of the memory blocks 211 shown in FIG. 4A. FIG. 15 is a sectional view illustrating the memory block BLKj taken along the line VII-VII′ shown in FIG. 14.

Referring to FIGS. 14 and 15, the memory block BLKj may include a structure extending along first to third directions.

A substrate 6311 may be provided. For example, the substrate 6311 may include a silicon material doped by a first type impurity. For example, the substrate 6311 may include a silicon material doped by a p-type impurity or a p-type well, e.g., a pocket p-well. The substrate 6311 may further include an n-type well surrounding the p-type well. In the embodiment, it is exemplarily assumed that the substrate 6311 is p-type silicon. However, the substrate 6311 is not limited to being p-type silicon.

First to a fourth conductive material layers 6321 to 6324 extending along the X-direction and the Y-direction may be disposed over the substrate 6311. The first to fourth conductive material layers 6321 to 6324 may be spaced apart from one another in the Z-direction.

Fifth to eighth conductive material layers 6325 to 6328 extending along the X-direction and the Y-direction may be disposed over the substrate 6311. The fifth to eighth conductive material layers 6325 to 6328 may be spaced apart from one another in the Z-direction. The fifth to eighth conductive material layers 6325 to 6328 may be spaced apart from the first to fourth conductive material layers 6321 to 6324 in the Y-direction.

A plurality of lower pillars DP may be formed to penetrate the first to fourth conductive material layers 6321 to 6324. Each of the lower pillars DP may be extended in the Z-direction. A plurality of upper pillars UP may be formed to penetrate the fifth to eighth conductive material layers 6325 to 6328. Each of the upper pillars UP may be extended in the Z-direction.

Each of the lower pillars DP and the upper pillars UP may include an internal material layer 6361, a middle layer 6362 and a surface layer 6363. The middle layer 6362 may serve as a channel of the cell transistor. The surface layer 6363 may include a blocking insulating layer, an electric charge storage layer, and a tunnel insulating layer.

The lower pillars DP and the upper pillars UP may be coupled through a pipe gate PG. The pipe gate PG may be formed in the substrate 6311. For example, the pipe gate PG may include substantially the same material as the lower pillars DP and the upper pillars UP.

A doping material layer 6312 doped with a second type impurity may be disposed over the lower pillars DP. The doping material layer 6312 may extend in the X direction and the Y direction. For example, the doping material layer 6312 doped with the second type impurity may include an n-type silicon material. The doping material layer 6312 doped with the second type impurity may serve as the common source line CSL.

Drains 6340 may be formed over each of the upper pillars UP. For example, the drain 6340 may include an n-type silicon material. First and second upper conductive material layers 6351 and 6352 may be formed over the drains 6340. The first and second upper conductive material layers 6351 and 6352 may be extended in the Y-direction.

The first and second upper conductive material layers 6351 and 6352 may be spaced apart from each other in the X-direction. For example, the first and second upper conductive material layers 6351 and 6352 may be made of metal. For example, the first and second upper conductive material layers 6351 and 6352 may be coupled to the drains 6340 through contact plugs. The first and second upper conductive material layers 6351 and 6352 may serve as first and second bit lines BL1 and BL2, respectively.

The first conductive material layer 6321 may serve as the source select line SSL, and the second conductive material layer 6322 may serve as the first dummy word line DWL1, and the third and fourth conductive material layers 6323 and 6324 may serve as the first and second main word lines MWL1 and MWL2, respectively. The fifth and sixth conductive material layers 6325 and 6326 may serve respectively as the third and fourth main word lines MWL3 and MWL4, the seventh conductive material layer 6327 may serve as the second dummy word line DWL2, and the eighth conductive material layer 6328 may serve as the drain select line DSL.

Each of the lower pillars DP and the first to fourth conductive material layers 6321 to 6324 adjacent to the lower pillar DP may form a lower string. Each of the upper pillars UP and the fifth to eighth conductive material layers 6325 to 6328 adjacent to the upper pillar UP may form an upper string. The lower string and the upper string may be coupled through the pipe gate PG. One end of the lower string may be coupled to the second-type doping material layer 6312 serving as the common source line CSL. One end of the upper string may be coupled to a corresponding bit line through the drain 6340. The lower string and the upper string are coupled through the pipe gate PG. A single lower string and a single upper string may form a single cell string coupled between the second-type doping material layer 6312 serving as the common source line CSL and a corresponding one of the upper conductive material layers 6351 and 6352 serving as the bit line BL.

That is, the lower string may include the source select transistor SST, the first dummy memory cell DMC1, and the first and second main memory cells MMC1 and MMC2. The upper string may include the third and fourth main memory cells MMC3 and MMC4, the second dummy memory cell DMC2 and the drain select transistor DST.

Referring to FIGS. 14 and 15, the upper string and the lower string may form the NAND string NS having a plurality of transistor structures TS. The transistor structure TS may be substantially the same as the transistors described with reference to FIG. 12.

FIG. 16 is an equivalent circuit diagram illustrating the memory block BLKj described with reference to FIGS. 14 and 15. FIG. 16 exemplarily shows first and second strings among the strings included in the memory block BLKj.

Referring to FIG. 16, the memory block BLKj may include a plurality of cell strings, each of which comprises a single upper string and a single lower string that are coupled through the pipe gate PG, as described with reference to FIGS. 14 and 15.

In the memory block BLKj, memory cells CG0 to CG31 stacked along a first channel layer CH1 (not shown), one or more source selection gates SSG, and one or more drain selection gates DSG may form a first string ST1. Memory cells CG0 to CG31 stacked along a second channel layer CH2 (not shown), one or more source selection gates SSG, and one or more drain selection gates DSG may form a second string ST2.

The first and second strings ST1 and ST2 may be coupled to a single drain selection line DSL and a single source selection line SSL. The first string ST1 may be coupled to a first bit line BL1, and the second string ST2 may be coupled to a second bit line BL2.

FIG. 16 shows the first and second strings ST1 and ST2 coupled to a single drain selection line DSL and a single source selection line SSL. In another embodiment, the first and second strings ST1 and ST2 may be coupled to a single source selection line SSL and a single bit line BL. In such case, the first string ST1 may be coupled to the first drain selection line DSL1, and the second string ST2 may be coupled to the second drain selection line DSL2. In another embodiment, the first and second strings ST1 and ST2 may be coupled to a single drain selection line DSL and a single bit line BL. In such case, the first string ST1 may be coupled to the first source selection line SSL1, and the second string ST2 may be coupled to the second source selection line SSL2.

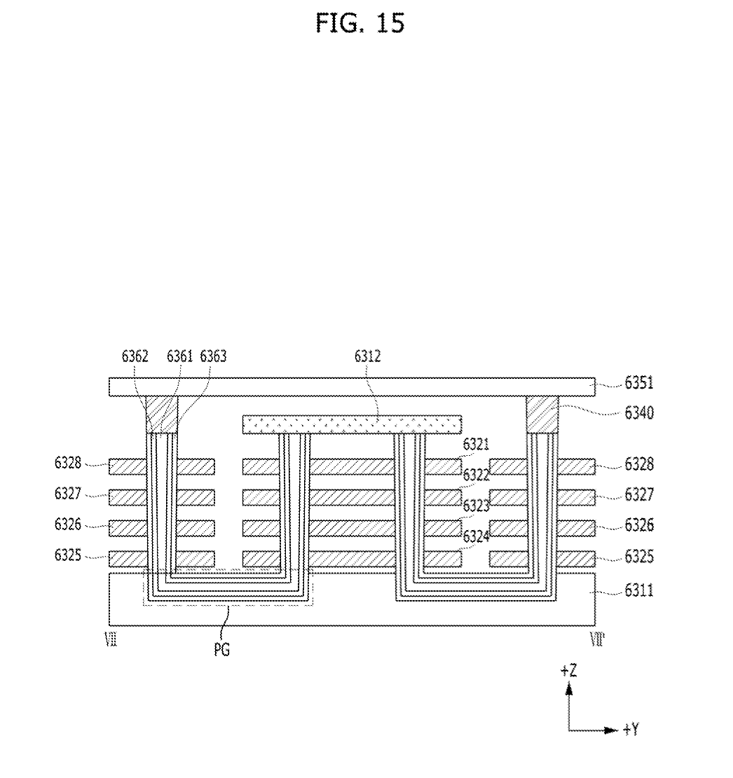

FIG. 17 is a block diagram schematically illustrating an electronic device 10000 including a memory controller 15000 and a semiconductor memory device 16000 in accordance with an embodiment of the present invention.

Referring to FIG. 17, the electronic device 10000 such as a cellular phone, a smart phone, or a tablet PC may include the semiconductor memory device 16000 implemented by a flash memory device and the memory controller 15000 to control the semiconductor memory device 16000.

The semiconductor memory device 16000 may correspond to the semiconductor memory device 200 described above with reference to FIGS. 3 to 13. The semiconductor memory device 16000 may store random data.

The memory controller 15000 may correspond to the memory controller described with reference to FIGS. 3 to 13. The memory controller 15000 may be controlled by a processor 11000 which controls overall operations of the electronic device 10000.

Data stored in the semiconductor memory device 16000 may be displayed through a display 13000 under the control of the memory controller 15000. The memory controller 15000 operates under the control of the processor 11000.

A radio transceiver 12000 may receive and output a radio signal through an antenna ANT. For example, the radio transceiver 12000 may convert the received radio signal from the antenna ANT into a signal to be processed by the processor 11000. Thus, the processor 11000 may process the converted signal from the radio transceiver 12000, and may store the processed signal in the semiconductor memory device 16000. Otherwise, the processor 11000 may display the processed signal through the display 13000.

The radio transceiver 12000 may convert a signal from the processor 11000 into a radio signal, and may output the converted radio signal to an external device through the antenna ANT.

An input device 14000 may receive a control signal for controlling operations of the processor 11000 or data to be processed by the processor 11000, and may be implemented by a pointing device such as a touch pad or a computer mouse, a key pad, or a keyboard.

The processor 11000 may control the display 13000 such that the data from the semiconductor memory device 16000, the radio signal from the radio transceiver 12000 or the data from the input device 14000 is displayed through the display 13000.

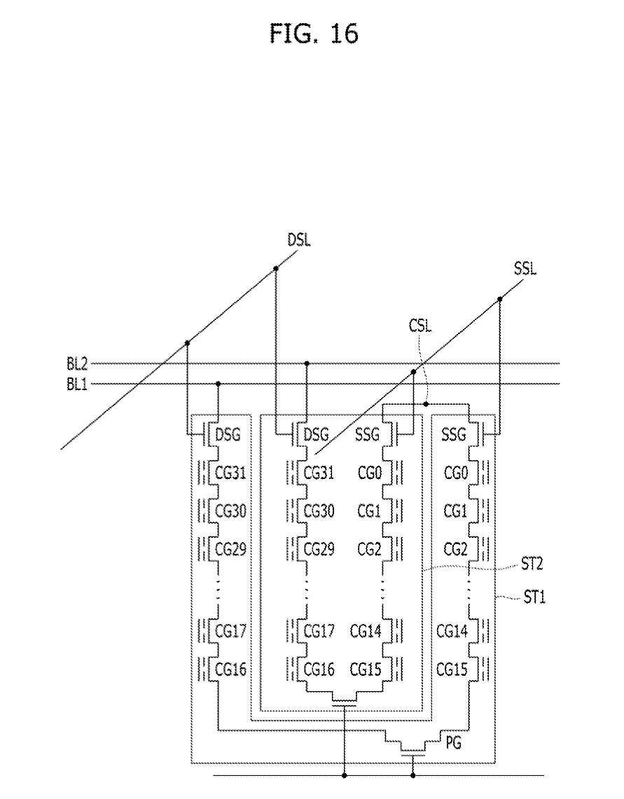

FIG. 18 is a block diagram schematically illustrating an electronic device 20000 including a memory controller 24000 and a semiconductor memory device 25000 in accordance with an embodiment of the present invention.

The memory controller 24000 and the semiconductor memory device 25000 may correspond to the memory controller 100 and the semiconductor memory device 200 described with reference to FIGS. 3 to 13, respectively.

Referring to FIG. 18, the electronic device 20000 may be implemented by a data processing device such as a personal computer (PC), a tablet computer, a net-book, an e-reader, a personal digital assistant (PDA), a portable multimedia player (PMP), an MP3 player, or an MP4 player, and may include the semiconductor memory device 25000, e.g., a flash memory device, and the memory controller 24000 to control operations of the semiconductor memory device 25000.

The electronic device 20000 may include a processor 21000 to control overall operations of the electronic device 20000. The memory controller 24000 may be controlled by the processor 21000.

The processor 21000 may display data stored in the semiconductor memory device 25000 through a display 23000 according to an input signal from an input device 22000. For example, the input device 22000 may be implemented by a pointing device such as a touch pad or a computer mouse, a key pad, or a keyboard.

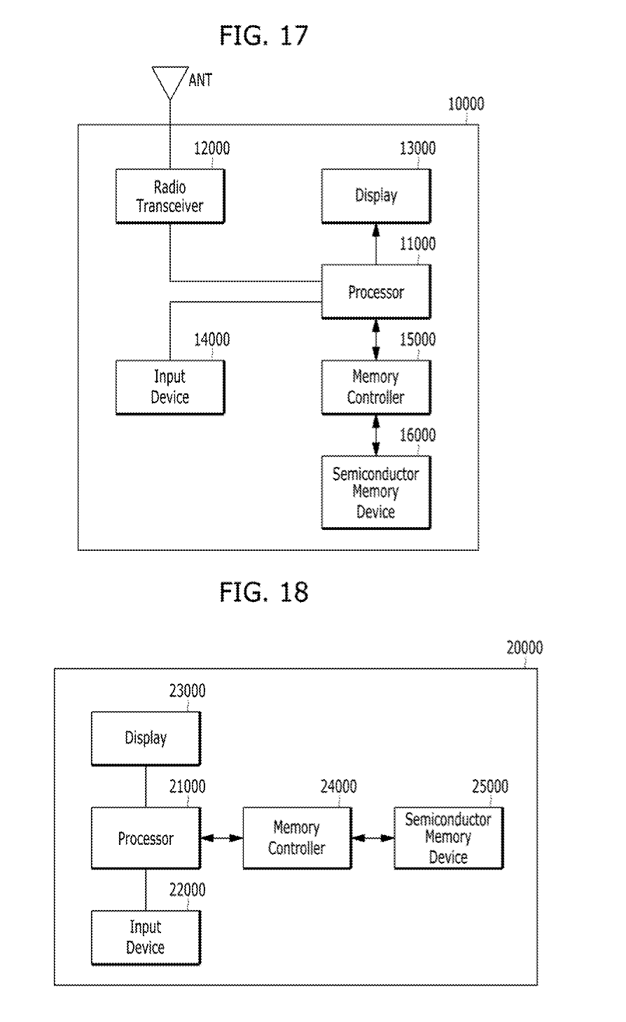

FIG. 19 is a block diagram schematically illustrating an electronic device 30000 including a controller 32000 and a semiconductor memory device 34000 in accordance with an embodiment of the present invention.

The controller 32000 and the semiconductor memory device 34000 may correspond to the memory controller 100 and the semiconductor memory device 200 described with reference to FIGS. 3 to 13, respectively.

Referring to FIG. 19, the electronic device 30000 may include a card interface 31000, the controller 32000, and the semiconductor memory device 34000, for example, a flash memory device.

The electronic device 30000 may exchange data with a host through the card interface 31000. The card interface 31000 may be a secure digital (SD) card interface or a multi-media card (MMC) interface, which does not limit the scope of the present invention. The card interface 31000 may interface the host and the controller 32000 according to a communication protocol of the host capable of communicating with the electronic device 30000.

The controller 32000 may control overall operations of the electronic device 30000, and may control data exchange between the card interface 31000 and the semiconductor memory device 34000. A buffer memory 33000 of the controller 32000 may buffer data transferred between the card interface 31000 and the semiconductor memory device 34000.

The controller 32000 may be coupled with the card interface 31000 and the semiconductor memory device 34000 through a data bus DATA and an address bus ADDRESS. In accordance with an embodiment, the controller 32000 may receive an address of data, which is to be read or written, from the card interface 31000, through the address bus ADDRESS, and may send it to the semiconductor memory device 34000. Further, the controller 32000 may receive or transfer data to be read or written through the data bus DATA connected with the card interface 31000 or the semiconductor memory device 34000.

When the electronic device 30000 is connected with the host such as a PC, a tablet PC, a digital camera, a digital audio player, a mobile phone, console video game hardware or a digital set-top box, the host may exchange data with the semiconductor memory device 34000 through the card interface 31000 and the controller 32000.

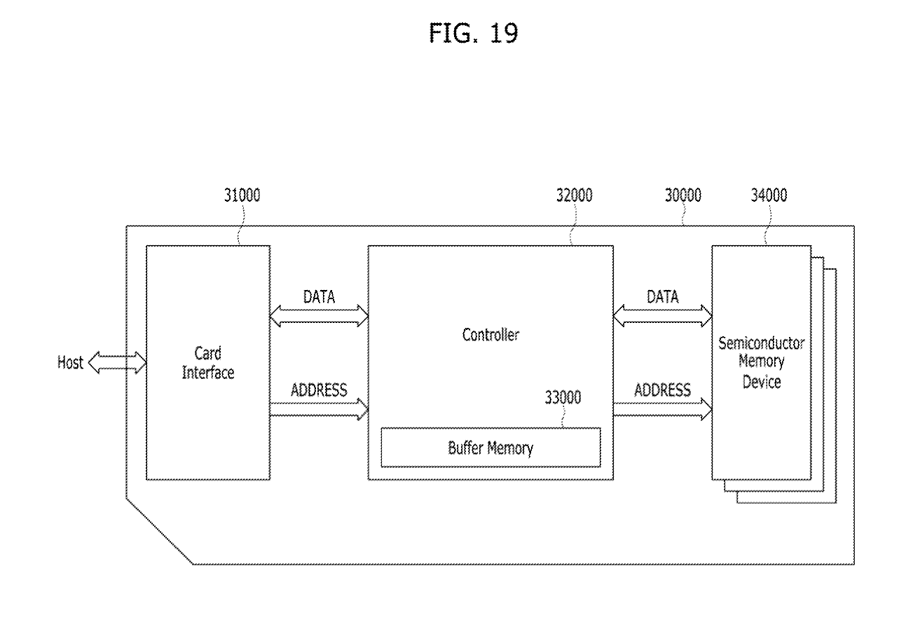

FIG. 20 is a block diagram schematically illustrating an electronic device 40000 including a memory controller 44000 and a semiconductor memory device 45000 in accordance with an embodiment of the present invention.

The memory controller 44000 and the semiconductor memory device 45000 may correspond to the memory controller 100 and the semiconductor memory device 200 described with reference to FIGS. 3 to 13, respectively.

Referring to FIG. 20, the electronic device 40000 may include the semiconductor memory device 45000, e.g., the flash memory device, the memory controller 44000 to control a data processing operation of the semiconductor memory device 45000, and a processor 41000 to control overall operations of the electronic device 40000.

Further, an image sensor 42000 of the electronic device 40000 may convert an optical signal into a digital signal, and the converted digital signal may be stored in the semiconductor memory device 45000 under the control of the processor 41000. Otherwise, the converted digital signal may be displayed through a display 43000 under the control of the processor 41000.

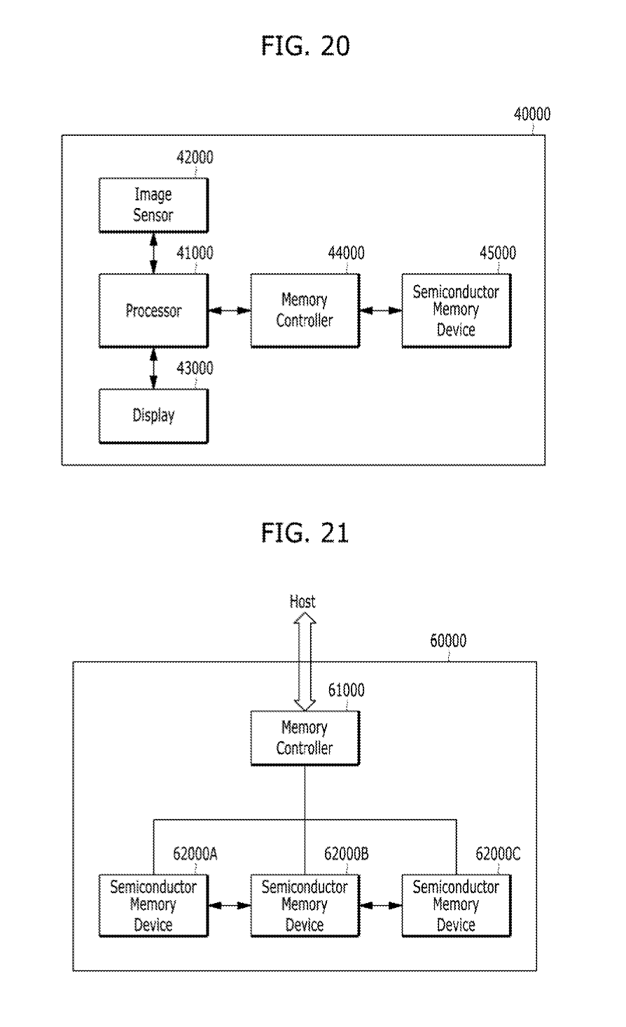

FIG. 21 is a block diagram schematically illustrating an electronic device 60000 including a memory controller 61000 and semiconductor memory devices 62000A, 62000B, and 62000C in accordance with an embodiment of the present invention.

The memory controller 61000 and each of the semiconductor memory devices 62000A, 62000B, and 62000C may correspond to the memory controller 100 and the semiconductor memory device 200 described with reference to FIGS. 3 to 13, respectively.

Referring to FIG. 21, the electronic device 60000 may be implemented by a data storage device such as a solid state drive (SSD).

The electronic device 60000 may include the plurality of semiconductor memory devices 62000A, 62000B, and 62000C and the memory controller 61000 to control a data processing operation of each of the semiconductor memory devices 62000A, 62000B, and 62000C.

The electronic device 60000 may be implemented by a memory system or a memory module.

For example, the memory controller 61000 may be implemented outside or inside the electronic device 60000.

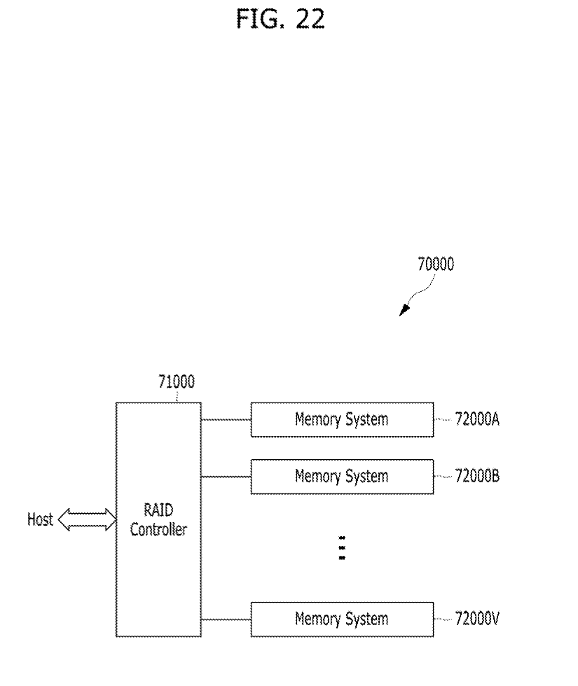

FIG. 22 is a block diagram of a data processing system including the electronic device 6000 described with reference to FIG. 21.

Referring to FIGS. 21 and 22, a data storage device 70000 may be implemented by a redundant array of independent disks (RAID) system. The data storage device 70000 may include a RAID controller 71000 and a plurality of memory systems 72000A to 72000N, where N is a natural number.

Each of the memory systems 72000A to 72000N may correspond to the electronic device 60000 described with reference to FIG. 21. The memory systems 72000A to 72000N may form a RAID array. The data storage device 70000 may be implemented by an SSD.

During a program operation, the RAID controller 71000 may output program data, which is output from a host, to one of the memory systems 72000A to 72000N according to one selected from a plurality of RAID levels based on RAID level information output from the host.

During a read operation, the RAID controller 71000 may transfer data, which is read from one of the memory systems 72000A to 72000N, to the host according to one of the RAID levels based on the RAID level information output from the host.

While the present invention has been described with respect to the specific embodiments, it will be apparent to those skilled in the art that various changes and modifications may be made without departing from the spirit and scope of the invention as defined in the following claims.

What is claimed is:

1. An operating method of a memory controller, comprising:
performing a first hard decision read operation based on a read retry table including an index representing a read environment of a semiconductor memory device, wherein the read retry table defines hard read voltage values for a plurality of hard read voltage levels of a multi-level cell; and
performing a second hard decision read operation by independently changing each of the hard read voltage levels based on the hard read voltage values of the read retry table when the first hard decision read operation fails.

2. The operating method of claim 1, wherein the second hard decision read operation is performed according to the hard read voltage levels by sequentially changing the hard read voltage values for each of the hard read voltage levels according to the index of the read retry table.

3. The operating method of claim 2, wherein the second hard decision read operation is performed according to the hard read voltage levels by sequentially changing the hard read voltage levels.

4. The operating method of claim 3, wherein the second hard decision read operation changes a first hard read voltage level while fixing other hard read voltage levels.

5. The operating method of claim 4, wherein the second hard decision read operation fixes the other hard read voltage levels to the hard read voltage values defined by the read retry table.

6. The operating method of claim 3,
wherein, after the second hard decision read operation is performed according to a first hard read voltage level by sequentially changing the hard read voltage values for the first hard read voltage level, the second hard decision read operation is performed according to a second hard read voltage level when the second hard decision read operation in response to the first hard read voltage level fails, and
wherein the first and second hard read voltage levels are included in the plurality of hard read voltage levels.

7. The operating method of claim 1, wherein the first hard decision read operation is performed when a hard decision read operation according to the hard read voltage levels that are set to initial hard read voltage values fails.

8. The operating method of claim 1, further comprising:
performing a soft decision read operation when the second hard decision read operation according to all of the hard read voltage values of the read retry table fails.

9. The operating method of claim 8, wherein one or more of the first and second hard decision read operations and the soft decision read operation are performed based on a low density parity check (LDPC) decoding process.

10. The operating method of claim 1, wherein the read environment of the semiconductor memory device includes one or more of a retention characteristic and a read disturbance characteristic.

11. A memory controller comprising:
a first means for performing a first hard decision read operation based on a read retry table including an index representing a read environment of a semiconductor memory device, wherein the read retry table defines hard read voltage values for a plurality of hard read voltage levels of a multi-level cell; and
a second means for performing a second hard decision read operation by independently changing each of the hard read voltage levels based on the hard read voltage values of the read retry table when the first hard decision read operation fails.

12. The memory controller of claim 11, wherein the second means performs the second hard decision read operation according to the hard read voltage levels by sequentially changing the hard read voltage values for each of the hard read voltage levels according to the index of the read retry table.

13. The memory controller of claim 12, wherein the second means performs the second hard decision read operation according to the hard read voltage levels by sequentially changing the hard read voltage levels.

14. The memory controller of claim 13, wherein the second means changes a first hard read voltage level while fixing other hard read voltage levels.

15. The memory controller of claim 14, wherein the second means fixes the other hard read voltage levels to the hard read voltage values defined by the read retry table.

16. The memory controller of claim 13,
wherein, after the second means performs the second hard decision read operation according to a first hard read voltage level by sequentially changing the hard read voltage values for the first hard read voltage level, the second means performs the second hard decision read operation according to a second hard read voltage level when the second hard decision read operation according to the first hard read voltage level fails, and
wherein the first and second hard read voltage levels are included in the plurality of hard read voltage levels.

17. The memory controller of claim 11, wherein the first means performs the first hard decision read operation when a hard decision read operation according to the hard read voltage levels that are set to initial hard read voltage values fails.

18. The memory controller of claim 11, further comprising:
a third means for performing a soft decision read operation when the second hard decision read operation according to all of the hard read voltage values of the read retry table fails.

19. The memory controller of claim 18, wherein one or more of the first to third means perform the first and second hard decision read operations and the soft decision read operation based on a low density parity check (LDPC) decoding process.

20. The memory controller of claim 11, wherein the read environment of the semiconductor memory device includes one or more of a retention characteristic and a read disturbance characteristic.
